(19) United States
(12) Patent Application Publication
(10) Pub. No.: US 2025/0005418 A1
(43) Pub. Date: Jan. 2, 2025

(54) SYSTEMS AND METHODS FOR SUPERCONDUCTING FLUX QUBIT READOUT

(71) Applicant: D-WAVE SYSTEMS INC., Burnaby (CA)

(72) Inventors: Kelly T. R. Boothby, Vancouver (CA); Min Jan Tsai, Richmond (CA); Berta Trullas Clavera, Vancouver (CA); Mauricio Reis Filho, Burnaby (CA); Paul I. Bunyk, Pt. Roberts, WA (US)

(21) Appl. No.: 18/710,133

(22) PCT Filed: Nov. 16, 2022
(86) PCT No.: PCT/US2022/079944

§ 371 Date: May 14, 2024

Related U.S. Application Data
(60) Provisional application No. 63/280,467, filed on Nov. 17, 2021.

(51) Int. Cl. G06N 10/40

(52) U.S. Cl. CPC G06N 10/40

(57) ABSTRACT

A superconducting flux qubit readout system may include an input-output system connected to at least one shift register, the shift register comprising a first set, a second set, and a third set of shift register stages arranged in series, the first set of shift register stages coupled to a first set of qubits by a first plurality of latches, and the second set of shift register stages coupled to a second set of qubits by a second plurality of latches. Reading out states of a first set of qubits may include: shifting qubit state information to first holding latches communicatively coupled to a shift register; obtaining, by each shift register stage of the first set of shift register stages, state information from the first holding latches; and, propagating information along the shift register.

### CROSS-REFERENCE TO RELATED APPLICATION

This patent application claims priority of U.S. Patent Application No. 63/280,467, filed on Nov. 17, 2021, the entire disclosure of which is hereby incorporated by reference herein for all purposes.

### BACKGROUND

### Field

The present systems and methods generally relate to readout systems and methods for superconducting quantum processors that comprise superconducting flux qubits.

### Superconducting Qubits

Superconducting qubits are solid state qubits based on circuits of superconducting materials. Operation of superconducting qubits is based on the underlying principles of magnetic flux quantization, and Josephson tunneling. Superconducting effects can be present in different configurations, and can give rise to different types of superconducting qubits including flux, phase, charge, and hybrid qubits. The different configurations can vary in the topology of the loops, the placement of the Josephson junctions, and the physical parameters of elements of the superconducting circuits, such as inductance, capacitance, and Josephson junction critical current.

### Quantum Processor

A quantum processor may take the form of a superconducting quantum processor. A superconducting quantum processor may include a number of qubits and associated local bias devices, for instance two or more superconducting qubits. A superconducting quantum processor may also employ coupling devices (i.e., “couplers”) providing communicative coupling between qubits.

In one implementation, the superconducting qubit includes a superconducting loop interrupted by a Josephson junction. The ratio of the inductance of the Josephson junction to the geometric inductance of the superconducting loop can be expressed as 2λLIc/Φ₀ (where L is the geometric inductance, I_{C} is the critical current of the Josephson junction, and Φ₀ is the flux quantum). The inductance and the critical current can be selected, adjusted, or tuned, to increase the ratio of the inductance of the Josephson junction to the geometric inductance of the superconducting loop, and to cause the qubit to be operable as a bistable device. In some implementations, the ratio of the inductance of the Josephson junction to the geometric inductance of the superconducting loop of a qubit is approximately equal to three.

In one implementation, the superconducting coupler includes a superconducting loop interrupted by a Josephson junction. The inductance and the critical current can be selected, adjusted, or tuned, to decrease the ratio of the inductance of the Josephson junction to the geometric inductance of the superconducting loop, and to cause the coupler to be operable as a monostable device. In some implementations, the ratio of the inductance of the Josephson junction to the geometric inductance of the superconducting loop of a coupler is approximately equal to, or less than, one.

Further detail and embodiments of example quantum processors that may be used in conjunction with the present systems and methods are described in U.S. Pat. Nos. 7,533,068; 8,008,942; 8,195,596; 8,190,548; and 8,421,053.

### Adiabatic Quantum Computation

Adiabatic quantum computation typically involves evolving a system from a known initial Hamiltonian (the Hamiltonian being an operator whose eigenvalues are the allowed energies of the system) to a final Hamiltonian by gradually changing the Hamiltonian. A simple example of an adiabatic evolution is:

$${H}_{e} = ( 1 - s ) {H}_{l} + {sH}_{f}$$

where Hᵢ is the initial Hamiltonian, H_{f} is the final Hamiltonian, Hₑ is the evolution or instantaneous Hamiltonian, and s is an evolution coefficient which controls the rate of evolution. As the system evolves, the s coefficient s goes from 0 to 1 such that at the beginning (i.e., s=0) the evolution Hamiltonian Hₑ is equal to the initial Hamiltonian Hᵢ and at the end (i.e., s=1) the evolution Hamiltonian Hₑ is equal to the final Hamiltonian H_{f} Before the evolution begins, the system is typically initialized in a ground state of the initial Hamiltonian Hᵢ and the goal is to evolve the system in such a way that the system ends up in a ground state of the final Hamiltonian H_{f} at the end of the evolution. If the evolution is too fast, then the system can be excited to a higher energy state, such as the first excited state. In the present systems and methods, an “adiabatic” evolution is considered to be an evolution that satisfies the adiabatic condition:

$$\dot{s} \vert 〈 1 \vert {dH}_{e} / ds \vert 0 〉 \vert = δ {g}^{2} ( s )$$

where \dot{s} is the time derivative of s, g(s) is the difference in energy between the ground state and first excited state of the system (also referred to herein as the “gap size”) as a function of s, and δ is a coefficient much less than 1.

The evolution process in adiabatic quantum computing may sometimes be referred to as annealing. The rate that s changes, sometimes referred to as an evolution or annealing schedule, is normally slow enough that the system is always in the instantaneous ground state of the evolution Hamiltonian during the evolution, and transitions at anti-crossings (i.e., when the gap size is smallest) are avoided. Further details on adiabatic quantum computing systems, methods, and apparatus are described in U.S. Pat. Nos. 7,135,701 and 7,418,283.

### Quantum Annealing

Quantum annealing is a computation method that may be used to find a low-energy state, typically preferably the ground state, of a system. Similar in concept to classical annealing, the method relies on the underlying principle that natural systems tend towards lower energy states because lower energy states are more stable. However, while classical annealing uses classical thermal fluctuations to guide a system to its global energy minimum, quantum annealing may use quantum effects, such as quantum tunneling, to reach a global energy minimum more accurately and/or more quickly than classical annealing. It is known that the solution to a hard problem, such as a combinatorial optimization problem, may be encoded in the ground state of a system Hamiltonian and therefore quantum annealing may be used to find the solution to such a hard problem. Adiabatic quantum computation is a special case of quantum annealing for which the system, ideally, begins and remains in its ground state throughout an adiabatic evolution. Thus, those of skill in the art will appreciate that quantum annealing systems and methods may generally be implemented on an adiabatic quantum computer, and vice versa. Throughout this specification and the appended claims, any reference to quantum annealing is intended to encompass adiabatic quantum computation unless the context requires otherwise.

Quantum annealing can be implemented via an algorithm that uses quantum mechanics as a source of disorder during the annealing process. The optimization problem is encoded in a Hamiltonian H_{P}, and the algorithm introduces strong quantum fluctuations by adding a disordering Hamiltonian H_{D} that does not commute with H_{P}. An example case is:

$${H}_{E} = {H}_{P} + Γ {H}_{D} ,$$

where Γ changes from a large value to substantially zero during the evolution and H_{E} may be thought of as an evolution Hamiltonian similar to Hₑ described in the context of adiabatic quantum computation above. The disorder is slowly removed by removing H_{D} (i.e., reducing Γ). Thus, quantum annealing is similar to adiabatic quantum computation in that the system starts with an initial Hamiltonian and evolves through an evolution Hamiltonian to a final “problem” Hamiltonian H_{P} whose ground state encodes a solution to the problem. If the evolution is slow enough, the system will typically settle in a local minimum close to the exact solution. The performance of the computation may be assessed via the residual energy (distance from exact solution using the objective function) versus evolution time. The computation time is the time required to generate a residual energy below some acceptable threshold value. In quantum annealing, H_{P} may encode an optimization problem and therefore H_{P} may be diagonal in the subspace of the qubits that encode the solution, but the system does not necessarily stay in the ground state at all times. The energy landscape of H_{P} may be crafted so that its global minimum is the answer to the problem to be solved, and low-lying local minima are good approximations.

The gradual reduction of F in quantum annealing may follow a defined schedule known as an annealing schedule. Unlike traditional forms of adiabatic quantum computation where the system begins and remains in its ground state throughout the evolution, in quantum annealing the system may not remain in its ground state throughout the entire annealing schedule. As such, quantum annealing may be implemented as a heuristic technique, where low-energy states with energy near that of the ground state may provide approximate solutions to the problem.

### Flux Qubit Readout in Adiabatic Quantum Computation and Quantum Annealing

In both adiabatic quantum computation and quantum annealing, a network of qubits is initiated in a first configuration and evolved by a quantum process to a second configuration in accordance with an annealing schedule. The second configuration is defined by the states of the qubits at the end of the quantum evolution. The qubit states are read out using a readout system. An important feature of adiabatic quantum computation and quantum annealing is that the qubit states typically only need to be read out at the end of the annealing schedule when the quantum evolution has finished. This means that the qubit states when read out actually correspond to classical states.

Systems and methods for flux qubit readout in processors designed to perform adiabatic quantum computation and/or quantum annealing are typically only used to read out the classical 0 and 1 states of the qubits at the end of a quantum evolution. This is in contrast to readout systems and methods in processors designed to perform gate-model and/or circuit-model quantum computation, where it can be necessary for the readout system to probe states of the qubits during the computation process without destroying those states.

### Frequency Multiplexed Resonant (FMR) Readout

Superconducting microwave resonators have been used in a variety of fields including, but not limited to, quantum computation and astronomy. For example, in quantum computation, superconducting resonators have been used to detect the state of qubits. In astronomy, superconducting microwave resonators have been used in Microwave Kinetic Inductance Detectors (MKIDs). In both cases, many resonators (detectors) can be coupled to a common transmission line and integrated through frequency domain multiplexing. Frequency domain multiplexing (FDM) is a technique in which a communication bandwidth is divided into a number of non-overlapping sub-bands, each sub-band used to carry a separate signal.

Using FMR technology, superconducting resonators of different resonant frequencies can be used for readout of multiple qubits. The resonators can share a common microwave transmission line by using frequency domain multiplexing.

### BRIEF SUMMARY

In one implementation, there is provided a superconducting circuit. The superconducting circuit includes: a plurality of qubits including a first set of qubits and a second set of qubits; at least one readout shift register; and a respective set of latches corresponding to each qubit of the plurality of qubits. Each readout shift register of the at least one readout shift register includes: a first set of shift register stages, a second set of shift register stages, and a third set of shift register stages. Latches of each set of latches are communicatively coupled to one another in series. For each readout shift register: at least one shift register stage of a respective first set of shift register stages is communicatively coupled to a respective qubit of the first set of qubits via a respective set of latches; at least one shift register stage of a respective second set of shift register stages is communicatively coupled to a respective qubit of the second set of qubits via a respective set of latches; and, each shift register stage of a respective third set of shift register stages is communicatively coupled to at least one of: a shift register stage of the first set of shift register stages and a shift register stage of the second set of shift register stages. Each shift register stage of a respective third set of shift register stages is to exclusively perform shift operations.

In some implementations, each shift register stage of each first set of shift register stages of the superconducting circuit is communicatively coupled to one shift register stage of a respective second set of shift register stages and one shift register of a respective third set of shift register stages. Each shift register stage of each second set of shift register stages of the superconducting circuit is communicatively coupled to one shift register stage of a respective first set of shift register stages and one shift register of a respective second set of shift register stages.

In some implementations, for each readout shift register of the superconducting circuit: all shift register stages of the first set of shift register stages are communicatively coupled to a first clock line, where the first clock line is operable to carry first clock signals to latch the first set of shift register stages; all shift register stages of the second set of shift register stages are communicatively coupled to a second clock line, where the second clock line is operable to carry second clock signals to latch the second set of shift register stages; and, all shift register stages of the third set of shift register stages are communicatively coupled to a third clock line, where the third clock line is operable to carry third clock signals that to latch the third set of shift register stages.

In some implementations, each set of latches includes at least: a first latch communicatively coupled to a respective qubit of the plurality of qubits; one or more intermediate latches, where at least one latch of the one or more intermediate latches is communicatively coupled to the first latch; and, a final latch communicatively coupled to a respective shift register stage and at least one latch of the one or more intermediate latches. All first latches are communicatively coupled to a first latch clock line operable to carry first latch clock signals to latch the first latches, all intermediate latches of the one or more intermediate latches are communicatively coupled to respective intermediate latch clock lines operable to carry intermediate latch clock signals to latch the at least one intermediate latches, and all final latches are communicatively coupled to a final latch clock line operable to carry final latch clock signals to latch the final latches.

In some implementations, each shift register stage of the first, the second, and the third sets of shift register stages of each readout shift register includes a Josephson junction operable to communicably receive a respective one of the first clock signals, the second clock signals, and the third clock signals. Each latch of the first, the one or more intermediate, and the final latches of each set of latches includes a Josephson junction operable to communicably receive a respective one of the first latch clock signals, the at least one intermediate latch clock signals, and the final latch clock signals.

In some implementations, shift register stages of the first, the second, and the third sets of shift register stages of each readout shift register, and the sets of latches include at least one material that exhibits superconducting behavior at and below a respective material critical temperature.

In some implementations, each shift register stage of the first, the second, and the third sets of shift register stages of each shift register, and each latch of each of the sets of latches includes a respective quantum flux parametron (QFP).

In some implementations, each readout shift register includes at least one terminating shift register stage communicatively coupled to a respective communication shift register. Each communication shift register is communicatively coupled to a respective readout interface.

In some implementations, each communication shift register includes alternating shift registers stages of a first, a second, and a third set of communication shift register stages that are respectively communicatively coupled to one of a first, a second, and a third communication clock line. Each one of the first, the second, and the third communication clock lines carry a respective clock signal to latch shift registers stages of a respective one of the first, the second, and the third set of communication shift register stages. Each shift register stage of the communication shift register includes a QFP.

In some implementations, each readout interface includes a superconducting microwave resonator that has a first and a second superconducting quantum interference device (SQUID) arranged in series along a superconducting loop. The terminating shift register stage of a respective communication shift register is inductively coupled to the second SQUID of the superconducting microwave resonator to transmit the qubit state information corresponding to qubits of the plurality of qubits to the readout interface.

In some implementations, the first and the second SQUIDs of the superconducting microwave resonator are operable as tunable non-linear inductors to independently tune a resonant frequency and a sensitivity of the superconducting microwave resonator.

In some implementations, the superconducting circuit includes a first plurality of readout shift registers arranged in parallel to one another along a major portion of a respective length of each readout shift register of the first plurality of readout shift registers. The plurality of qubits includes a first plurality of qubits, which includes a first subset of the first set of qubits and a first subset of the second set of qubits that cross the first plurality of readout shift registers at a non-zero angle, A a pair of readout shift registers of the first plurality of readout shift registers crosses each qubit of the first plurality of qubits, and each qubit of the first plurality of qubits is coupled to one readout shift register of a respective pair of readout shift register via communicative coupling of one superconducting loop of the respective qubit to a respective set of latches.

In some implementations, the superconducting circuit further includes a second plurality of readout shift registers arranged in parallel to one another along a major portion of a respective length of each readout shift register of the second plurality of readout shift registers and that cross the first plurality of readout shift registers at a non-zero angle. The plurality of qubits includes a second plurality of qubits that includes second subset of the first set of qubits and a second subset of the second set of qubits that cross the second plurality of readout shift registers at a non-zero angle. A pair of readout shift registers of the second plurality of readout shift registers crosses each qubit of the second plurality of qubits. Each qubit of the second plurality of qubits is coupled to one readout shift register of a respective pair of readout shift registers via communicative coupling of one superconducting loop of the respective qubit to a respective set of latches.

In some implementations, each readout shift register of the first and the second pluralities of readout shift registers includes two terminating shift register stages that are communicatively coupled to a respective communication shift register. Each communication shift register is communicatively coupled to a respective readout interface.

In some implementations, the first set of shift register stages includes at least a first subset of first shift register stages and a second subset of first shift register stages. Each shift register stage of the first subset of first shift register stages is communicatively coupled to a first clock line operable to carry first clock signals to latch the first subset of first shift register. Each shift register stage of the second subset of first shift register stages is communicatively coupled to a second clock line operable to carry second clock signals to latch the second subset of first shift register stages. The second set of shift register stages includes at least a first subset of second shift register stages and a second subset of second shift register stages. Each shift register stage of the first subset of second shift register stages is communicatively coupled to a third clock line operable to carry third clock signals to latch the first subset of second shift register stages. Each shift register stage of the second subset of second shift register stages is communicatively coupled to a fourth clock line operable to carry fourth clock signals to latch the second subset of second shift register stages. Each shift register stage of the third set of shift register stages is communicatively coupled to a fifth clock lines operable to carry fifth clock signals to latch shift register stages of the third set of shift register stages.

In some implementations, the superconducting circuit includes at least one pair of readout shift registers and at least one interstitial bus. Readout shift registers of each pair of readout shift registers are communicatively coupled to one another via a respective interstitial bus of the at least one interstitial bus. Each interstitial bus is communicatively coupled to a respective readout interface via a respective communication shift register.

In some implementations, each interstitial bus of the at least one interstitial bus includes one shift register stage belonging to each of the first, the second, and the third sets of shift register stages. Each communication shift register comprises a plurality of communication shift register stages. The one shift register stage of the third set of shift register stages of the interstitial bus is communicatively coupled to a first communication shift register stage of the communication shift register.

In some implementations, the superconducting circuit further includes a first plurality of readout shift registers that are parallel to one another along a majority of a respective length of each readout shift register of the first plurality of readout shift registers and oriented in a first direction. The at least one pair of readout shift registers that are communicatively coupled to one another via a respective interstitial bus includes each nearest-neighbor pair of readout shift registers of the first plurality of readout shift registers. The superconducting circuit includes a second plurality of shift readout registers that are parallel to one another along a majority of a respective length of each readout shift register of the second plurality of readout shift registers and oriented in a second direction that is different to the first direction. The at least one pair of readout shift registers that are communicatively coupled to one another via a respective interstitial bus further includes each nearest-neighbor pair of readout shift registers of the second plurality of readout shift registers. The superconducting circuit includes at least two connection buses, where each connection bus communicatively couples one shift register of the first plurality of readout shift registers to one shift register of the second plurality of readout shift registers.

In some implementations, qubits of the plurality of qubits that are communicatively coupled to shift registers of the first plurality of readout shift registers include: a first, a second, and a third plurality of qubits. Each one of the first, the second, and the third pluralities of qubits include a respective one of a first, a second, and a third subset of the first set of qubits and a respective one of a first, a second, and a third subset of the second set of qubits. Each qubit of the first, the second, and the third pluralities of qubits includes a Josephson junction that is communicatively coupled to a respective one of a first, a second, and a third analog interface. All qubits communicatively coupled to a same one shift register of the first plurality of readout shift registers belong to a same one of: the first plurality of qubits, the second plurality of qubits, and the third plurality of qubits. Qubits of the plurality of qubits that are communicatively coupled to shift registers of the second plurality of readout shift registers include: a fourth, a fifth, and a sixth plurality of qubits. Each one of the fourth, the fifth, and the sixth pluralities of qubits include a respective one of a fourth, a fifth, and a sixth subset of the first set of qubits and a respective one of a fourth, a fifth, and a sixth subset of the second set of qubits. Each qubit of the fourth, the fifth, and the sixth pluralities of qubits includes a Josephson junction that is communicatively coupled to a respective one of a fourth, a fifth, and a sixth analog interface. All qubits communicatively coupled to a same one shift register of the second plurality of readout shift registers belong to a same one of: the fourth plurality of qubits, the fifth plurality of qubits, and the sixth plurality of qubits.

In some implementations, for the first plurality of readout shift registers, the first set of shift register stages comprises: a first, a second, a third, and a fourth subset of first shift register stages. Each shift register stage of the first subset of first shift register stages is communicatively coupled to: one qubit of the first plurality of qubits, and a clock line carrying a first subset-first clock signal. Each shift register stage of the second subset of first shift register stages is communicatively coupled to: one qubit of the second plurality of qubits, and a clock line carrying a second subset-first clock signal. Each shift register stage of the third subset of first shift register stages is communicatively coupled to: one qubit of the third plurality of qubits, and a clock line carrying a third subset-first clock signal. Each shift register stage of the fourth subset of first shift register stages is communicatively coupled to: one qubit of any one of the first, the second, and the third pluralities of qubits, and a clock line carrying a fourth subset-first clock signal. The second set of shift register stages includes: a first, a second, a third, and a fourth subset of second shift register stages. Each shift register stage of the second subset of first shift register stages is communicatively coupled to: one qubit of the first plurality of qubits, and a clock line carrying a first subset-second clock signal. Each shift register stage of the second subset of second shift register stages is communicatively coupled to: one qubit of the second plurality of qubits, and a clock line carrying a second subset-second clock signal. Each shift register stage of the third subset of second shift register stages is communicatively coupled to: one qubit of the third plurality of qubits, and a clock line carrying a third subset-second clock signal. Each shift register stage of the fourth subset of second shift register stages is communicatively coupled to: one qubit of any one of the first, the second, and the third pluralities of qubits, and a clock line carrying a fourth subset-second clock signal. Each shift register stage of the third set of shift register stages is communicatively coupled to a clock line carrying a third clock signal.

In some implementations, for the second plurality of readout shift registers: the first set of shift register stages includes: a fifth, a sixth, a seventh, and an eighth subset of first shift register stages. Each shift register stage of the fifth subset of first shift register stages is communicatively coupled to: one qubit of the fourth plurality of qubits, and the clock line carrying the first subset-first clock signal. Each shift register stage of the sixth subset of first shift register stages is communicatively coupled to: one qubit of the fifth plurality of qubits, and the clock line carrying the second subset-first clock signal. Each shift register stage of the seventh subset of first shift register stages is communicatively coupled to: one qubit of the sixth plurality of qubits, and the clock line carrying the third subset-first clock signal. Each shift register stage of the eighth subset of first shift register stages is communicatively coupled to: one qubit of any one of the fourth, the fifth, and the sixth pluralities of qubits, and the clock line carrying the fourth subset-first clock signal. The second set of shift register stages includes: a fifth, a sixth, a seventh, and an eighth subset of second shift register stages. Each shift register stage of the fifth subset of second shift register stages is communicatively coupled to: one qubit of the fourth plurality of qubits, and the clock line carrying the first subset-first clock signal. Each shift register stage of the sixth subset of second shift register stages is communicatively coupled to: one qubit of the fifth plurality of qubits, and the clock line carrying the second subset-first clock signal. Each shift register stage of the seventh subset of first shift register stages is communicatively coupled to: one qubit of the sixth plurality of qubits, and the clock line carrying the third subset-first clock signal. Each shift register stage of the eighth subset of first shift register stages is communicatively coupled to: one qubit of any one of the fourth, the fifth, and the sixth pluralities of qubits, and the clock line carrying the fourth subset-first clock signal. Each shift register stage of the third set of shift register stages is communicatively coupled to the clock line carrying the third clock signal.

In one implementation, there is provided a method of transmitting data from a plurality of qubits including a first set of qubits and a second set of qubits. Sets of latches communicatively couple the plurality of qubits to at least one shift register that includes: a first set of shift register stages, a second set of shift register stages, and a third set of shift register stages. Each qubit of the first set of qubits is communicatively coupled to a respective shift register stage of the set of first shift register stages via a respective set of latches, and each qubit of the second set of qubits is communicatively coupled to a respective shift register stage of the set of second shift register stages via a respective set of latches. The method includes shifting qubit state information of each qubit of the plurality of qubits to a respective holding latch of a corresponding set of latches. The method includes obtaining, by each shift register stage of the first set of shift register stages, qubit state information of each qubit of the first set of qubits from a respective holding latch via a respective final latch. The method includes propagating the qubit state information of the first set of qubits along at least one shift register stage of the second set of shift register stages and at least one shift register stage of the third set of shift register stages to read out the qubit state information of the first set of qubits. The method includes obtaining, by each shift register stage of the second set of shift register stages, qubit state information of each qubit of the second set of qubits from a respective holding latch via a respective final latch. The method includes propagating the qubit state information of the second set of qubits along at least one shift register stage of the third set of shift register stages to read out the qubit state information of the second set of qubits.

In some implementations, the shifting qubit state information of each qubit of a plurality of qubits to a respective holding latch of a corresponding set of latches includes: applying a first latch latching clock signal to a respective Josephson junction of each first latch of a respective set of latches to transmit the qubit state information of each qubit of the plurality of qubits to a respective first latch.

In some implementations, more than one latch communicatively couples each first latch and a final latch of each set of latches, and the holding latch is a latch most proximate and communicatively coupled to the final latch. Other ones of the more than one latch are one or more intermediate latches that communicatively couple each first latch to each holding latch. The method alternatingly includes: i) applying one or more intermediate latch latching clock signals to a respective Josephson junction of each one or more intermediate latches, and a holding latch latching clock signal to a respective Josephson junction of each holding latch of a respective set of latches, and ii) applying one or more intermediate latch suppression clock signals to a respective Josephson junction of the one or more intermediate latches of a respective set of latches.

In some implementations, the obtaining, by each shift register stage of the first set of shift register stages, qubit state information of each qubit of the first set of qubits from a respective holding latch via a respective final latch includes: loading the qubit state information of each qubit of the plurality of qubits held in a respective holding latch into a respective final latch of each set of latches; and, loading the qubit state information of each qubit of the first set of qubits from a respective final latch to a respective shift register stage of the first set of shift register stages.

In some implementations, the loading the qubit state information of each qubit of the plurality of qubits held in a respective holding latch into a respective final latch of each set of latches includes applying a final latch latching clock signal to a respective Josephson junction of each final latch. The loading the qubit state information of each qubit of the first set of qubits from a respective final latch to a respective shift register stage of the first set of shift register stages includes applying a first latching clock signal to a respective Josephson junction of each shift register stage of the first set of shift register stages.

In some implementations, the obtaining, by each shift register stage of the second set of shift register stages, qubit state information of each qubit of the second set of qubits from a respective holding latch via a respective final latch includes: shifting the qubit state information of each qubit of the plurality of qubits from a respective holding latch to a respective final latch of each set of latches; and, loading the qubit state information of each qubit of the second set of qubits from a respective final latch to a respective shift register stage of the second set of shift register stages.

In some implementations, the shifting the qubit state information of each qubit of the plurality of qubits from a respective holding latch to a respective final latch of each set of latches includes applying a final latch latching clock signal to a Josephson junction of each final latch and applying a holding latch suppression clock signal to a Josephson junction of each holding latch. The loading the qubit state information of each qubit of the second set of qubits from a respective final latch to a respective shift register stage of the second set of shift register stages includes applying a second latching clock signal to Josephson junctions of each shift register stage of the second set of shift register stages.

In some implementations, the method includes applying: a final latch suppression signal to a respective Josephson junction of each final latch, a first suppression clock signal to Josephson junctions of each shift register stage of the first set of shift register stages, and one of a second or third latching clock signal to propagate qubit state information from each shift register stage of the first set of shift register stages to a communicatively coupled shift register stage of a respective one of the second or third sets of shift register stages. The method includes applying: a final latch suppression signal to a respective Josephson junction of each final latch, a second suppression clock signal to Josephson junctions of each shift register stage of the second set of shift register stages and one of a first or a third latching clock signal to propagate qubit state information from each shift register stage of the second set of shift register stages to a communicatively coupled shift register stage of a respective one of the first or third sets of shift register stages.

In some implementations, the at least one shift register includes a plurality of shift registers that are parallel along a majority of a respective length of each shift register of the plurality of shift registers and at least two shift registers of the plurality of shift registers crosses each qubit of the first and the second sets of qubits. The propagating the qubit state information of the first set of qubits and the propagating the qubit state information of the second set of qubits includes propagating qubit state information of each qubit along one of the at least two shift registers of the first plurality of shift registers that crosses said qubit, where each qubit being exclusively communicatively coupled to the one of the at least two shift registers, and the propagating is based on first, second, and third clock signals. The propagating includes shifting the qubit state information from a terminating shift register stage of the one of the at least two shift registers to a shift register stage of a respectively communicatively coupled communication shift register. The propagating includes propagating the qubit state information along the respective communication shift register to a respective readout interface based on first, second, and third communication clock signals.

In some implementations, the propagating qubit state information of each qubit along one of the at least two shift registers of the plurality of shift registers that crosses said qubit includes propagating qubit state information of all qubits coupled to a same one of the shift registers as one another along the shift register in a same direction as one another.

In some implementations, the propagating qubit state information of each qubit along one of the at least two shift registers of the plurality of shift registers that crosses said qubit includes: propagating qubit state information of qubits on a first side of a defined shift register location along the one of the at least two shift registers in a first direction; and propagating qubit state information of qubits on a second side of the defined shift register location along the one of the at least two shift registers in a second direction, wherein the second direction opposes the first direction.

In some implementations, the at least one shift register includes at least one shift register pair, where shift registers of each shift register pair are communicatively coupled to one another via a respective interstitial bus. For each shift register pair, the propagating the qubit state information of the first set of qubits and the propagating the qubit state information of the second set of qubits includes: propagating the qubit state information along a first shift register of the shift register pair; shifting the qubit state information from the first shift register of the shift register pair into a shift register stage of the interstitial bus; propagating the qubit state information along a first portion of the interstitial bus; loading the qubit state information in the interstitial bus into a shift register stage of a communication shift register; propagating the qubit state information along the communication shift register; and shifting the qubit state information to a readout interface.

In some implementations, the method further includes: propagating the qubit state information along a second portion of the interstitial bus; shifting the qubit state information from the interstitial bus to a communicatively coupled shift register stage of a second shift register of the shift register pair; and propagating the qubit state information along the second shift register of the shift register pair in a direction opposing a direction of propagation along the first shift register of the shift register pair.

In some implementations, the at least one shift register includes a first plurality of shift registers, and each pair of nearest-neighbor shift registers of the first plurality of shift registers is communicatively coupled by a respective interstitial bus. The propagating the qubit state information of the first set of qubits and the propagating the qubit state information of the second set of qubits further includes: propagating qubit state information of qubits coupled to a first subset of shift registers of the first plurality of shift registers along a respectively coupled shift register in a first direction; and propagating qubit state information of qubits coupled to a second subset of shift registers of the first plurality of shift registers along a respectively coupled shift register in a second direction, in which the second direction opposes the first direction

In some implementations, the at least one shift register further includes a second plurality of shift registers, and each pair of nearest-neighbor shift registers of the second plurality of shift registers is communicatively coupled by a respective interstitial bus. The second plurality of shift registers cross the first plurality of shift registers at an angle. At least one corner bus communicatively couples one shift register of the first plurality of shift registers to one shift register of the second plurality of shift registers. The propagating the qubit state information of the first set of qubits and the propagating the qubit state information of the second set of qubits further includes: propagating qubit state information of qubits coupled to a first subset of shift registers of the second plurality of shift registers along a respectively coupled shift register in a third direction; propagating qubit state information of qubits coupled to a second subset of shift registers of the first plurality of shift registers along a respectively coupled shift register in a fourth direction; and, shifting the qubit state information of qubits coupled to a shift register of the first plurality of shift registers into a shift register of the second plurality of shift registers.

In some implementations, the at least one shift register includes a first plurality of shift registers, and each pair of nearest-neighbor shift registers of the first plurality of shift registers is communicatively coupled by a respective interstitial bus. The plurality of qubits comprises: a first plurality of qubits including a first subset of qubits of the first and the second sets of qubits; a second plurality of qubits including a second subset of qubits of the first and the second sets of qubits; and, a third plurality of qubits including a third subset of qubits of the first and the second sets of qubits. Each qubit coupled to a same shift register of the first plurality of shift registers belongs to a same one of the first, the second, and the third pluralities of qubits. The obtaining, by each shift register stage of the first set of shift register stages, qubit state information of each qubit of the first set of qubits from a respective holding latch via a respective final latch includes: obtaining qubit state information of qubits of the first set of qubits belonging to one of the first, the second, or the third pluralities of qubits. The obtaining, by each shift register stage of the second set of shift register stages, qubit state information of each qubit of the second set of qubits from a respective holding latch via a respective final latch includes: obtaining qubit state information of qubits of the second set of qubits belonging to the one of the first, the second, or the third pluralities of qubits.

In some implementations, the obtaining qubit state information of qubits of the first set of qubits belonging to one of the first, the second, or the third pluralities of qubits includes applying a first set of latching clock signals to a subset of the first shift register stages that are correspondingly communicatively coupled to the qubits of the first set of qubits belonging to the one of the first, the second, or the third pluralities of qubits. The obtaining qubit state information of qubits of the second set of qubits belonging to the one of the first, the second, or the third pluralities of qubits includes applying a second set of latching clock signals to a subset of the second shift register stages that are correspondingly communicatively coupled to the qubits of the second set of qubits belonging to the one of the first, the second, or the third pluralities of qubits. T propagating the qubit state information of the first set of qubits and the propagating the qubit state information of the second set of qubits includes applying suppression clock signals to at least one of shift register stages of the first and the second sets of shift register stages that are adjacent to a communication shift register and are communicatively coupled to the other ones of the first, the second, or the third pluralities of qubits, and at least one shift register stage of each interstitial bus.

In some implementations, the propagating the qubit state information of the first set of qubits and the propagating the qubit state information of the second set of qubits includes: propagating the qubit state information of the qubits belonging to the one of the first, the second, or the third pluralities of qubits on a first side of a defined shift register location along shift registers that are communicatively coupled to the one of the first, the second, and the third pluralities of qubits in a first direction; and propagating the qubit state information of the qubits belonging to the one of the first, the second, or the third pluralities of qubits on a second side of the defined shift register location along shift registers that are communicatively coupled to the one of the first, the second, and the third pluralities of qubits in a second direction that opposes the first direction.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements, and may have been solely selected for ease of recognition in the drawings.

FIG. 1 is a schematic diagram of an example hybrid computing system including a digital computer and an analog computer in accordance with the present systems and devices.

FIG. 2A is a schematic diagram of example readout chains of a readout system for an example quantum processor, in accordance with the present systems and devices.

FIG. 2B is a schematic diagram of an alternative implementation of the example readout chains of FIG. 2A.

FIG. 2C is a schematic diagram of a portion of an example readout system using the readout chains of FIG. 2B.

FIG. 3A is a schematic diagram of a portion of an example readout system for an example quantum processor, in accordance with the present systems and devices.

FIG. 3B is a schematic diagram of an example readout system for an example quantum processor, which incorporates the portion of the example readout system of FIG. 3A.

FIG. 4 is a schematic diagram of a portion of an example readout system for an example quantum processor in accordance with the present systems and devices.

FIG. 5 is a top plan view an example full-processor readout system, which incorporates the example portion of the example readout system of FIG. 4.

FIG. 6 is a schematic diagram of a superconducting circuit comprising a frequency and sensitivity tunable resonator (FASTR) in accordance with the present systems and devices.

FIG. 7 is a schematic diagram of an example qubit in accordance with the present systems and devices.

FIG. 8 is a flowchart of an example method to transmit qubit state information in a quantum processor, in accordance with the present systems and devices.

FIG. 9A is a schematic diagram of one superconducting circuit configuration to read out the portion of an example readout system of FIG. 3A.

FIG. 9B is a schematic diagram of another superconducting circuit configuration to read out the portion of an example readout system of FIG. 3A.

FIG. 10A is a schematic diagram of one superconducting circuit configuration to read out a portion of the example readout system of FIG. 5.

FIG. 10B is a schematic diagram of another superconducting circuit configuration to perform a first pass for read out of a portion of the example readout system of FIG. 5.

FIG. 10C is a schematic diagram of another superconducting circuit configuration to perform a second pass for read out of a portion of the example readout system subsequent to performing the first pass of FIG. 10B.

### DETAILED DESCRIPTION

### Preamble

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems (for example digital computer systems, superconducting computers, quantum computer systems, and server computers), and/or communications networks have not been shown or described in detail to avoid unnecessarily obscuring descriptions of the implementations.

Unless the context requires otherwise, throughout the specification and claims that follow, the word “comprising” is synonymous with “including”, and is inclusive or open-ended (i.e., does not exclude additional, unrecited elements or method acts).

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a”, “an”, and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

In classical electrical circuits, complicated and elaborate operations may be carried out by a particular arrangement of simple switching devices, such as transistors. Examples of such arrangements include shift registers, memory arrays, adders, flip-flops, and the like. In the evolving field of superconducting electronics, and in particular superconducting quantum computing, it may be useful to develop circuits that implement superconducting analogues of each of these arrangements. These arrangements may similarly be constructed using simple switching devices; however, classical switching devices such as the transistor are not always appropriate in the superconducting regime. Thus, in many superconducting systems it is important to establish a basic superconducting logic device with which many other circuits and operations may be realized.

An application of superconducting electronics that is of particular interest is in the field of quantum computing. Superconducting circuits are capable of exploiting quantum effects on a macroscopic scale, providing a mechanism for the implementation of quantum computation that is much more manageable than some of the alternatives. As discussed, the fundamental unit of quantum computation is the qubit. Superconducting qubits may come in a variety of forms, including the superconducting flux qubit. A quantum processor may then comprise any number of such superconducting flux qubits. Thus, in implementing such a quantum processor, techniques for fabricating large numbers of superconducting flux qubits may be developed, as well as a solid understanding of the operation of such devices. The present systems, methods and apparatuses describe the use of the basic superconducting flux qubit structure as superconducting switching device in a quantum processor. In an exemplary embodiment, an arrangement of superconducting flux qubits may be implemented as a superconducting flux-based shift register.

### Example Hybrid Computing System

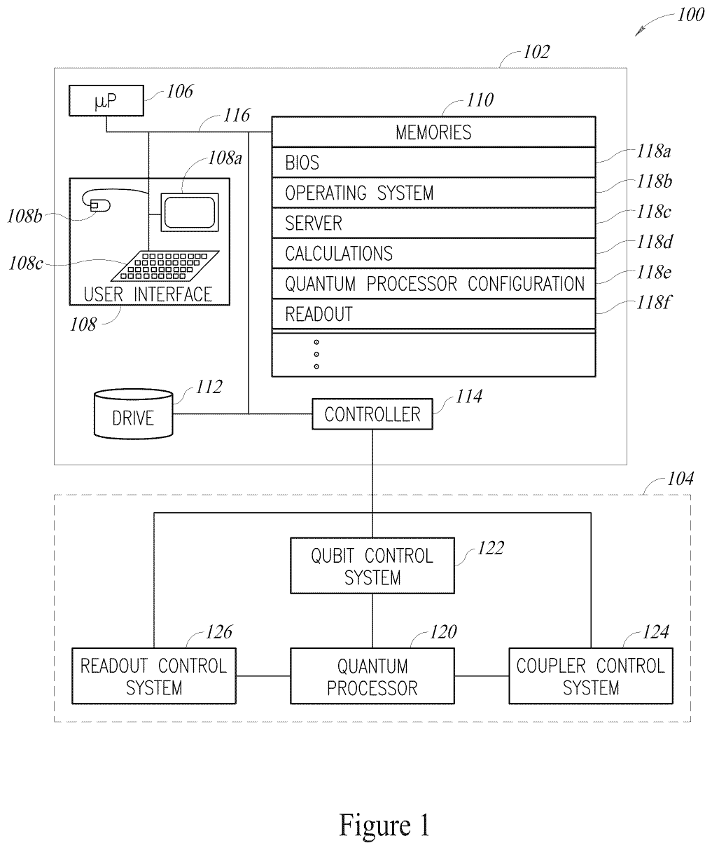

FIG. 1 illustrates a hybrid computing system 100 comprising a digital computer 102. The example digital computer 102 includes one or more digital processors 106 that may be used to perform classical digital processing tasks. Digital computer 102 may further include at least one system memory 116, and at least one system bus 120 that couples various system components, including system memory 110 to digital processor(s) 106. System memory 110 may store one or more sets of processor-executable instructions, which may be referred to as modules (collectively, 118).

The digital processor(s) 106 may be any logic processing unit or circuitry (for example, integrated circuits), such as one or more central processing units (“CPUs”), graphics processing units (“GPUs”), digital signal processors (“DSPs”), application-specific integrated circuits (“ASICs”), programmable gate arrays (“FPGAs”), programmable logic controllers (“PLCs”), etc., and/or combinations of the same.

In some implementations, hybrid computing system 100 comprises an analog computer 104, which may include one or more quantum processors 120. Quantum processor 120 may include at least one superconducting integrated circuit. Digital computer 102 may communicate with analog computer 104 via, for instance, a controller 114. Certain computations may be performed by analog computer 104 at the instruction of digital computer 102.

Digital computer 102 may include a user input/output subsystem 108. In some implementations, user input/output subsystem includes one or more user input/output components such as a display 108a, a mouse 108b, and/or a keyboard 108c.

System bus 116 may employ any known bus structures or architectures, including a memory bus with a memory controller, a peripheral bus, and a local bus. System memory 110 may include non-volatile memory, such as read-only memory (“ROM”), static random-access memory (“SRAM”), Flash NAND; and volatile memory such as random-access memory (“RAM”) (not shown).

Digital computer 102 may also include other non-transitory computer- or processor-readable storage media or non-volatile memory 112. Non-volatile memory 112 may take a variety of forms, including: a hard disk drive for reading from and writing to a hard disk (for example, a magnetic disk), an optical disk drive for reading from and writing to removable optical disks, and/or a solid state drive (SSD) for reading from and writing to solid state media (for example NAND-based Flash memory). Non-volatile memory 112 may communicate with digital processor(s) via system bus 116 and may include appropriate interfaces or controllers 114 coupled to system bus 116. Non-volatile memory 112 may serve as long-term storage for processor- or computer-readable instructions, data structures, or other data (sometimes called program modules or modules 118) for digital computer 102.

Although digital computer 102 has been described as employing hard disks, optical disks and/or solid-state storage media, those skilled in the relevant art will appreciate that other types of non-transitory and non-volatile computer-readable media may be employed. Those skilled in the relevant art will appreciate that some computer architectures employ non-transitory volatile memory and non-transitory non-volatile memory. For example, data in volatile memory may be cached to non-volatile memory or a solid-state disk that employs integrated circuits to provide non-volatile memory.

Various processor- or computer-readable and/or executable instructions, data structures, or other data may be stored in system memory 110. For example, system memory 110 may store instructions for communicating with remote clients and scheduling use of resources including resources on the digital computer 102 and analog computer 104.

The processor-executable instructions and data may, for example, include a basic input and output system set of instructions or “module” 118a which, when executed, configures digital computer 102 for operation on boot up. The processor-executable instructions and data may, for example, include an operating system set of instructions or “module” 118b which, when executed, configures digital computer 102 for operation, for instance providing various file management services and user interface services. The processor-executable instructions and data may, for example, include a server set of instructions or “module” 118c which, when executed, configures the digital computer 102 for operation as a server to provide access by other computers to information and services. The processor-executable instructions and data may, for example, include a set of instructions or “module” 118d which, when executed, configures digital computer 102 to perform various calculations associated with converting problems into a problem graph and/or post-processing of potential solutions generated by analog computer 104. The processor-executable instructions and data may, for example, include a quantum processor set of instructions or “module” 118e which, when executed, configures the digital computer 102 to map problems from a problem graph to a hardware graph for embedding in a quantum processor 120 of analog computer 104 for execution. The processor-executable instructions and data may, for example, include a read out set of instructions or “module” 118f which, when executed, configures digital computer 102 to perform various read out functions associated with reading out potential solutions to problems from quantum computer 104.

Analog computer 104 may include at least one analog processor such as quantum processor 120. Analog computer 104 may be provided in an isolated environment, for example, in an isolated environment that shields the internal elements of the quantum computer from heat, magnetic field, and other external noise. The isolated environment may include a refrigerator, for instance a dilution refrigerator, operable to cryogenically cool the analog processor, for example to temperature below approximately 1 K.

Analog computer 104 may include programmable elements such as qubits, couplers, and other devices (also referred to herein as controllable devices). Each coupler may be selectively operable to couple a respective pair of qubits. Qubits may be read out via a readout control system 126, which may be operatively coupled to control various interfaces operable to read out a state of each of the qubits, for example using the structures and processes described herein. Readout results may be sent to other computer- or processor-readable instructions of digital computer 102. Qubits may be controlled via a qubit control system 122, operatively coupled to control each of the qubits, for example via various interfaces, i.e., inductive interfaces that selectively couple a flux to the qubit. Qubit control system 122 may include on-chip Digital to Analog Converters (DACs) and analog lines that are operable to apply a bias to a target device. Couplers that couple qubits may be controlled via a coupler control system 124, which may be operatively coupled to control each of the couplers, for example via various interfaces, i.e., inductive interfaces that selectively couple a flux to the coupler to set a strength of coupling or “coupling strength” of the coupler. Coupler control system 124 may include tuning elements such as on-chip DACs and analog lines.

In one implementation, quantum processor 120 is a superconducting quantum processor including a number of qubits and associated couplers providing communicative coupling between qubits. The plurality of qubits may be arranged to form an interconnected topology (which, hereinafter may also be referred to as a “topology”). Further details and embodiments of example quantum processors that may be used in conjunction with the present systems and devices are described in, for example, U.S. Pat. Nos. 7,533,068; 8,008,942; 8,195,596; 8,190,548; 8,421,053; and 9,710,758.

Couplers can provide communicative coupling between qubits in a quantum processor. Coupling can be, for example, between adjacent and/or non-adjacent qubits. Unless expressly indicated otherwise, as used herein and in the claims, the terms couple, couples, coupling and variations of such means direct or indirect communicative coupling or communications between two or more components.

There are various types of quantum processors, such as quantum annealing processors and gate-model quantum processors. Quantum annealing processors generally follow an annealing schedule, which may be determined by the digital computer 102. This process can be described in various ways (e.g., annealing some annealing-time variable s from 0 to 1, changing the energy of a transverse field, and/or mixing a problem Hamiltonian with a disordering Hamiltonian). A simple annealing schedule might involve linearly varying the state of the system (e.g., decrementing s, reducing the energy of the transverse field, and/or moving from a state where the disordering Hamiltonian dominates to one where the problem Hamiltonian dominates.) At least some implementations, quantum annealing processors can execute problems “in reverse”—e.g., starting in a classical state with low (e.g., zero) traverse field and annealing toward what would ordinarily be considered an initial state with a high transverse field (e.g., having an energy dominating the energy of the problem Hamiltonian). Examples of such reverse annealing techniques are provided by, for example, U.S. Pat. No. 11,100,416.

In some implementations, qubit control system 122 and coupler control system 124 may be used to implement a quantum annealing schedule as described herein on analog processor 104. In accordance with some implementations of the present disclosure, a quantum processor, such as quantum processor 120, may be designed to perform quantum annealing and/or adiabatic quantum computation.

Alternatively, a quantum processor, such as quantum processor 120, may be a universal quantum computer, and may be designed to perform universal adiabatic quantum computing, or other forms of quantum computation such as gate model-based quantum computation.

### Example Readout System

Various respective systems, components, structures and algorithms for implementing such are described herein. Many of the described systems, components, structures and algorithms may be implemented individually, while some may be implemented in combination with one another.

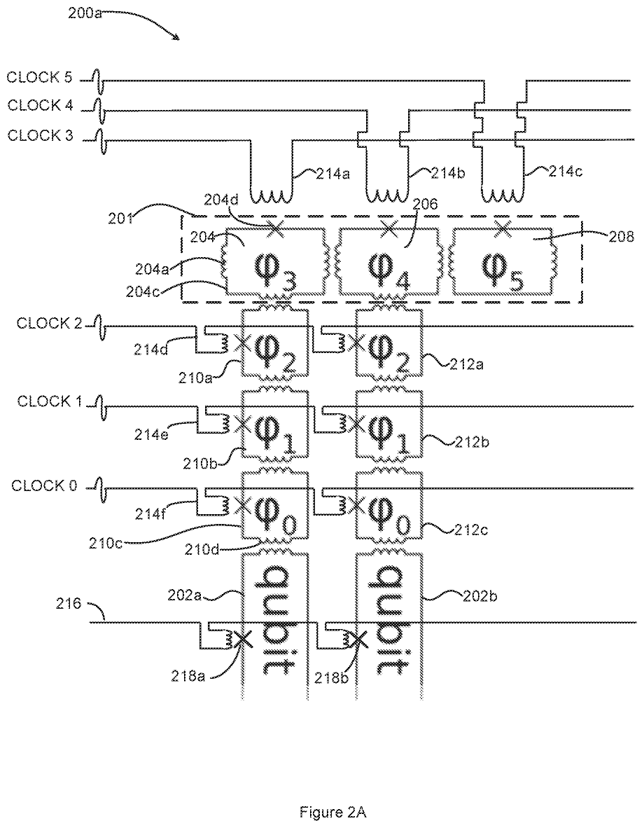

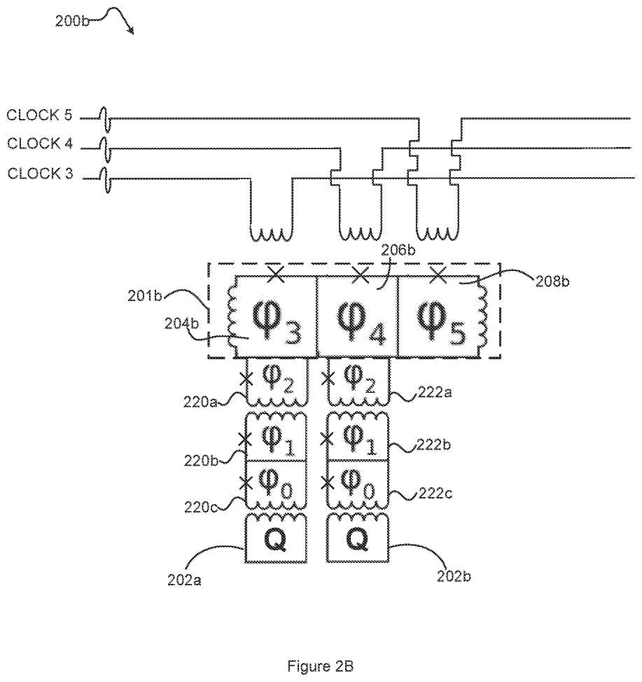

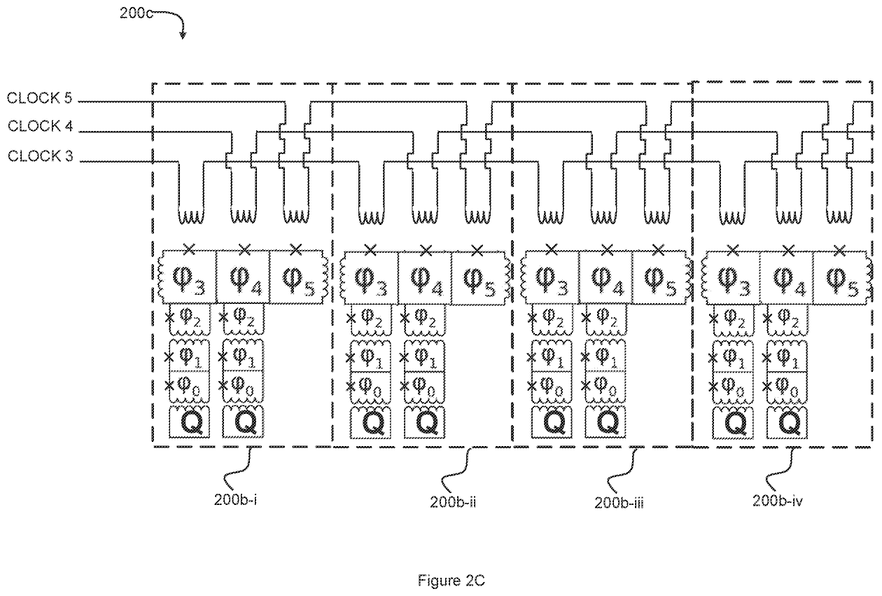

FIG. 2A is a schematic diagram of a superconducting circuit including example readout chains of a readout system for an example quantum processor, in accordance with the present systems and devices. Superconducting circuit 200a may be included as part of a readout control system for reading out qubit state information from a quantum processor. In some implementations, superconducting circuit 200a may be a portion of readout control system 126 used to read out qubit state information from quantum processor 120 of analog computer 104.

Superconducting circuit 200a includes a shift register 201. Shift register 201 may comprise, for example, a plurality of shift register stages (204, 206, 208) arranged in series. In superconducting circuit 200a, first shift register stage 204 is communicatively coupled to second shift register stage 206. Additionally, second shift register stage 206 is communicatively coupled to third shift register stage 208.

In Figure A, each of first, second, and third shift register stages 204, 206, 208 are shown to include transformers (also referred to as inductive interfaces or inductors, only one transformer 204a is pointed out in FIG. 2A) to communicatively couple first, second, and third shift register stages 204, 206, 208 to successive shift register stages and to additional components. Here, the transformers provide an inductive interface between shift register stages 204, 206, 208; though, this is only an example. In some implementations, some or all of interfaces between shift register stages 204, 206, 208 are transformers 204a that provide an inductive interface between components of superconducting circuit 200a. In alternative implementations, some or all of interfaces between first, second, and third shift register stages 204, 206, 208 may not include a transformer, and can instead have a galvanic interface between components of superconducting circuit 200a.

Shift register 201 is communicatively coupled to a first qubit 202a and a second qubit 202b (only a portion of each illustrated), for example, via one or more latches. In superconducting circuit 200a, first shift register stage 204 of shift register 201 is communicatively coupled to first qubit 202a via a first plurality of latches comprising a first shift register-proximate latch 210a, a first intermediate latch 210b, and a first qubit-proximate latch 210c, which are successively coupled to one another in series. Similarly, second shift register stage 206 of shift register 201 is communicatively coupled to second qubit 202b via a second plurality of latches comprising a second shift register-proximate latch 212a, a second intermediate latch 212b, and a second qubit-proximate latch 212c, which are successively coupled to one another in series.

In FIG. 2A, each latch of first plurality of latches 210a, 210b, 210c and second plurality of latches 212a, 212b, 212c are shown to include transformers (only one transformer 210d is pointed out in FIG. 2A) to communicatively couple a latch to one of: a successive latch of a respective plurality of latches, a corresponding one of first or second shift register stages 204, 206, and a corresponding one of first or second qubit 202a, 202b. Each transformer is to provide inductive coupling between components; however, this is only one example of a coupling interface. In alternative implementations, some or all of the coupling interfaces of the latches are not transformers 210d, and galvanic interfaces can be used to electrically couple components of superconducting circuit 200a. In some implementations, some or all of transformers 210d provide an inductive interface between components of superconducting circuit 200a.

Each one of first, second, and third shift register stages 204, 206, 208, each latch of the first and second pluralities of latches 210, 212, and first and second qubits 202a, 202b comprise at least a material that exhibits superconducting behavior at and below a critical temperature. Examples of superconducting materials include but are not limited to: niobium, aluminum, and tantalum. In some implementations, all of the above-listed components of superconducting circuit 200a may include a same superconducting material. In alternative implementations, components of the above-listed components of superconducting circuit 200a may include one or more different superconducting materials, each having a respective critical temperature.

In some implementations, such as the implementation shown in FIGS. 2A, each one of first, second, and third shift register stages 204, 206, 208 and each latch of the first and second pluralities of latches 210a, 210b, 210c; 212a, 212b, 212c is a quantum flux parametron (QFP). QFPs are superconducting Josephson junction devices similar in structure to compound rf-SQUIDs. The name “quantum flux parametron”, however, encompasses both the operation and the structure of the Josephson junction device, not simply structure alone.

In some implementations, a superconducting qubit can also be used as a QFP and can be denoted as a “latching qubit”. Herein, each one of first, second, and third shift register stages 204, 206, 208 and each latch of the first and second pluralities of latches 210a, 210b, 210c; 212a, 212b, 212c can also be referred to as a “latching component”. Each latching component can comprise a superconducting loop 204c (only one pointed out for first shift register stage 204) including transformer 204a. Here, transformer 204a is an inductor that inductively couples to a signal line (not shown in FIG. 2A). Each latching component can also comprise a Josephson junction 204d (only one pointed out for first shift register stage 204), which can be inductively coupled to a separate signal line (not shown in FIG. 2A to reduce visual clutter). In some implementations, each Josephson junction 204d may be a compound Josephson junction (CJJ) or a compound-compound Josephson junction (CCJJ).

The coupling of each latching component to other components of superconducting circuit 200a can be used to control the energy of the latching component to establish a specific potential energy curve. A barrier of the potential energy curve of a double-well potential can be controllable by a signal coupled to a latching component via its Josephson junction 204d.

The schematic diagram of the latching components that are shown in FIG. 2A are intended to be illustrative and serves as an example of an embodiment. Those of skill in the art will appreciate that many alterations may be made to the circuit to accommodate specific system requirements. For example, superconducting loop 204c may be of an alternate shape, such as square or circular there may be more or fewer than two Josephson junctions as part of Josephson junction 204d; and, additional Josephson junctions may also be inserted in superconducting loop 204c. All such alterations are specific to the exact system in which the latching component is being implemented, while the general principles behind operating latching qubits according to the present systems, methods and apparatus remain substantially unchanged.

In superconducting circuit 200a, Josephson junctions 204d of first shift register stage 204, second shift register stage 206, and third shift register stage 208 are inductively coupled to respective clock line signals via respective clock line interfaces 214a, 214b, and 214c. For instance, FIG. 2A shows that Josephson junction 204d of first shift register stage 204 is inductively coupled to a clock signal carried by CLOCK 3 via first clock line interface 214a.

In superconducting circuit 200a, Josephson junctions 204d of latches of first and second pluralities of latches 210, 212 are inductively coupled to clock line signals via respective clock line interfaces 214d, 214e, and 214f (only one of each called out). First and second shift register-proximate latches 210a, 212a are both communicatively coupled to a clock signal carried by CLOCK 2. First and second intermediate latches 210b, 212b are both communicatively coupled to a clock signal carried by CLOCK 1. First and second qubit-proximate latches 210c, 212c are both communicatively coupled to a clock signal carried by CLOCK 0.

The clock signals control the operation of a respectively coupled shift register stage or latch. Throughout this specification and the appended claims, the terms “clock” and “clock signal” are frequently used to refer to a controllable signal. Those of skill in the art, however, will appreciate that a controllable signal may be embodied by other signals or devices in an electric circuit or other medium (such as light) and can be either periodic or non-periodic. Thus, the terms “clock” and “clock signal” are used herein in their broadest sense and are meant to encompass all manner of administering a controllable signal.

For further detail on use of QFPs and/or latching qubits as shift register stages as part of a superconducting shift register, see U.S. Pat. No. 7,843,209.

Herein, a clock signal may include latching signals and suppression signals that govern the behavior of a latching component coupled to a corresponding clock line carrying the clock signal. Coupling of a latching signal to the latching component can “latch” the latching component, such that the latching component retains qubit state information for the duration of a latching signal of the clock signal. Coupling of a suppression signal to the latching component can “suppress” the latching component, such that qubit state information stored in the latching component is no longer held, for instance, until new information is loaded by coupling of another latching signal of the clock signal to the latching component. In some implementations, latching signals can be clock HIGH signals and suppression signals can be clock LOW signals, or vice vera. A latching component can transition between latching and suppressing qubit state information based on the portion of the clock signal coupled to the latching component at a given instance in time.

Herein, “loading” qubit state information into a first latching component can refer to an operation in which qubit state information is transmitted to, and held in, the first latching component. A loading operation is initiated by application of a first latching clock signal to a Josephson junction of the first latching component. Once qubit state information is loaded into the first latching component, it is held there until the first latching component is suppressed.

Herein, “shifting” qubit state information from a first latching component to a second latching component can refer to an operation where qubit state information is initially held in one latching component (e.g., the first latching component and is moved to a next successive latching component (e.g., the second latching component) such that it is no longer stored in the first latching component. A shift operation can be performed by the following sequence: continuously holding the qubit state information in the first latching component for the duration of a first latching clock signal; loading information into the second latching component based on a second latching clock signal, while all other neighboring latching components are suppressed (excepting the first latching component); and lastly, suppressing the qubit state information in the first latching component based on a first suppression clock signal.

While the above is described with respect to two latching components the same technique can be employed with three or even more latching component to successively move qubit state information through each of a series arrangement of the latching components in succession.

The terms “propagating” and “cycling” as used herein can refer to performing shift operations across one or more latching components arranged in series with one another.

Although the depicted superconducting circuit 200a of FIG. 2A provides three latches that communicatively couple each qubit to shift register 201, it will be appreciated that more or fewer latches may be provided, as appropriate for the characteristics of a given system.

First and second qubits 202a, 202b respectively include a first and a second qubit Josephson junction 218a, 218b. In some implementation, qubit Josephson junctions 218a, 218b can be CJJs or CCJJs. First qubit Josephson junction 218a of first qubit 202a and second qubit Josephson junction 218b of second qubit 202b are both communicatively coupled to an analog line 216 via an interface. In some implementations, analog lines 216 can be used to couple a control signal to first and second qubits 202a, 202b that tunes the first and second qubits 202a to have a determined or specified tunneling term of a Hamiltonian.

When performing readout using superconducting circuit 200a, qubits state information from qubits 202a, 202b is transmitted to other components of a hybrid computing system, such as computing system 100, via shift register 201. Each shift register stage 204, 206, 208 of shift register 201 transmits one bit of qubit information in the form of discrete magnetic flux quanta. In superconducting circuit 200a, each of first and second shift register stages 204, 206 are coupled to: a respective input signal from one of first and second qubits 202a, 202b via first and second pluralities of latches 210a, 210b, 201c; 212a, 212b, 212c; an output signal line, which is a respective successive shift register stage (for example, second shift register stage 206 receives the output of first shift register stage 204 and third shift register stage 208 receives the output of second shift register stage 206); and, a clock signal line, which is a respective one of CLOCK 3 and CLOCK 4. Third shift register stage 208 is coupled to: an input signal from a preceding shift register; an output signal line (not shown in FIG. 2A but can be, for example, a communication shift register and/or a readout interface as described later herein); and a clock signal line, which is CLOCK 5.

To read out qubit state information using superconducting circuit 200a, qubit state information corresponding to first and second qubits 202a, 202b is first loaded and latched into first and second qubit-proximate latches 210c, 212c at the instant that a CLOCK 0 latching signal is coupled to first and second qubit-proximate latches 210c, 212c to establish a barrier in a potential energy curve. First and second qubit-proximate latches 210c, 212c remained latched and retain the qubit state information for the duration of the CLOCK 0 latching signal. Then, qubit state information is shifted from first and second qubit-proximate latches 210c, 212c to first and second intermediate latches 210b, 212b on coupling to a CLOCK 1 latching signal. Following the duration of the CLOCK 0 latching signal, first and second qubit-proximate latches 210c, 212c are suppressed to no longer hold the qubit state information. This occurs after first and second intermediate latches 210b, 212b are latched. The qubit state information remains stored in first and second intermediate latches 210b, 212b for the duration of the CLOCK 1 latching signal.

Reading out qubit state information from superconducting circuit 200a, employs two passes. Herein, a pass refers to a series of shift operations used to transmit qubit state information from one of first and second pluralities of latches 210, 212 through shift register 201.

A first pass is used to read out qubit state information corresponding to first qubit 202a. To perform the first pass, the qubit state information is transmitted from first and second intermediate latches 210b, 212b to first and second shift-register proximate latches 210a, 212a on coupling to a CLOCK 2 latching signal. However, as the duration of CLOCK 1 latching signal is greater than that of the first pass, the qubit state information also remains stored in latched first and second intermediate latches 210b, 212b. Then, the qubit state information in first shift register-proximate latch 210a is shifted to first shift register stage 204 on a CLOCK 3 latching signal. Subsequent to the latching of first shift register stage 204, first and second shift-register proximate latches 210a, 212a are suppressed. The qubit state information of first qubit 202a is propagated along successive shift register stages 206, 208 in a stepwise manner through latching and suppression of second and third register stages 206, 208 based on a CLOCK 4 signal and a CLOCK 5 signal until the qubit state information is shifted out of shift register 201 to an additional structure (not shown in FIG. 2A).

A second pass is used to read out qubit state information corresponding to second qubit 202b. To perform the second pass, the qubit state information stored in first and second intermediate latches 210b, 212b is shifted to first and second shift register-proximate latches 210a, 212a on a CLOCK 2 latching signal. During the second pass, once first and second shift register-proximate latches 210a, 212a are latched, first and second intermediate latches 210b, 212b are suppressed to no longer store the qubit state information. Then, qubit state information corresponding to second qubit 202b in second shift register-proximate latch 212a is shifted to second shift register stage 206 on a CLOCK 4 latching signal. At this point, second shift register stage 206 is latched and first and second shift register-proximate latches 210a, 212a are suppressed. The qubit state information is propagated through third shift register stage 208 and shifted out of shift register 201 through latching and suppression of based on a CLOCK 5 signal.

After the first and second passes, all qubit state information of first and second qubits 202a, 202b coupled to shift register 201 is read out.

In an alternative implementation, a first pass can be used to read out qubit state information from second qubit 202b and a second pass can be used to read out qubit state information from first qubit 202a. In such an implementation, the qubit state information in second shift-register proximate latch 212a is propagated to second shift register stage 206 and shifted out of shift register 201 while the first and second intermediate latches 210b, 212b remained in a latched state. Then, qubit state information is transmitted from first and second intermediate latches 210b, 212b to first and second shift-register proximate latches 210a, 212a, and afterwards first and second intermediate latches 210b, 212b are suppressed before qubit state information corresponding to first qubit 202a is shifted through shift register 201.

As qubit state information is only initially loaded into first and second sets of latches 210, 212 coupled to first and second shift register stages 204, 206 during operation, readout of the qubits of superconducting circuit 200a has two-phase operation. Since third shift register stage 208 is not directly coupled to a unique set of latches that serve as a unique qubit readout signal path, third shift register stage 208 exclusively performs shift operations and serves as a “spacing stage”. The spacing stage is used to bridge empty space and to maintain phase alignments across a readout system structure. Qubit state information that has been loaded into first and second shift register stages 204, 206 is shifted through the spacing stage in a stepwise manner during operation.

In some existing readout systems for quantum processors, a similar portion of a readout system to superconducting circuit 200a may include qubits coupled to all three shift register stages of a superconducting shift register. Thus, readout of such a system may have a three-phase operation of qubits. Only one qubit may be read out at a time, requiring three passes of the superconducting circuit.

The two-phase operation of superconducting circuit 200a may beneficially decrease an overall readout time of qubit state information from a quantum processor, as described further herein.

FIG. 2B is a schematic diagram of an alternative implementation of the example readout chains of FIG. 2A. Like superconducting circuit 200a of FIG. 2A, superconducting circuit 200b includes a shift register 201b comprising three shift register stages that are communicatively coupled in series: first shift register stage 204b, second shift register stage 206b, and third shift register stage 208b. First shift register stage 204b is communicatively coupled to first qubit 202a via a first plurality of latches, and second shift register stage 206b is communicatively coupled to second qubit 202b via a second plurality of latches. First and second pluralities of latches respectively comprise: a first or second shift register-proximate latch 220a or 222a, a first or second intermediate latch 220b or 222b, and a first or second qubit-proximate latch 220c or 222c.

Although clock lines for only CLOCK 3, CLOCK 4, and CLOCK 5 signals are shown in FIG. 2B, it is to be understood that clock lines to carry CLOCK 0, CLOCK 1, and CLOCK 2 signals are also included in superconducting circuit 200b and are omitted for the purposes of visual clarity only.

In superconducting circuit 200b, second shift register stage 206b is galvanically coupled to first and third shift register stage 204b, 208b. Conversely, first and third shift register stages 204b, 208b are each shown to include additional transformers that inductively couple first and third shift register stages 204b, 208b to external structures. This arrangement provides magnetic gaps in a readout system of a quantum processor, which can advantageously improve design flexibility and limit transmission of electrical noise throughout superconducting circuit 200b.

As well, superconducting circuit 200b illustrates that first and second shift register-proximate latches 220a and 222a are galvanically coupled to first and second shift register stages 204b and 206b, respectively. First and second shift register-proximate latches 220a and 222a are then respectively inductively coupled to first and second intermediate latches 220b and 222b, which are respectively galvanically coupled to first and second qubit-proximate latches 220c and 222c. First and second qubit-proximate latches 220c and 222c are inductively respectively coupled to first and second qubits 202a and 202b.

The inductive coupling between first and second intermediate latches 220b, 222b and first and second shift register-proximate latches 220a, 220b creates additional magnetic gaps in superconducting circuit 200b having similar benefits to those described above. As well, these additional magnetic gaps may assist in mitigating accidental long resonators resulting from the galvanic coupling of all the shift register stages of shift register 201b.

FIG. 2C is a schematic diagram of a portion of an example readout system using the readout chains of FIG. 2B. Superconducting circuit 200c includes a tiled arrangement of superconducting circuit 200b (here, including superconducting circuits 200b-i, 200b-ii, 200b-iii, and 200b-iv) to provide a larger portion of an example readout system. A shift register of superconducting circuit 200c can be comprised of a repeating sequence of first, second, and third shift register stages 204b, 206b, 208b (FIG. 2B) that are successively coupled to one another in series. Here, each pair of adjacent first and third shift register stages 204b, 208b in successively adjacent ones of superconducting circuit 200b are inductively coupled to one another in order to transmit qubit state information from one grouping of first, second, and third shift register stages 204b, 206b, 208b to the next. For example, qubit state information is propagated along the shift register from third shift register stage 208b of superconducting circuit 200b-i to first shift register stage 204b of superconducting circuit 200b-ii across respective inductive interfaces. Likewise, qubit state information is propagated along the shift register from third shift register stage 208b of superconducting circuit 200b-ii to first shift register stage 204b of superconducting circuit 200b-iii across respective inductive interfaces. Similarly, qubit state information is propagated along the shift register from third shift register stage 208b of superconducting circuit 200b-iii to first shift register stage 204b of superconducting circuit 200b-iv across respective inductive interfaces.

In FIG. 2C, it is shown that clock line carrying CLOCK 3 signals is communicatively coupled to first shift register stage 204b in each one of superconducting circuit 200b. Similarly, clock lines carrying CLOCK 4 and CLOCK 5 signals are respectively communicatively coupled to all second and third shift register stage 206b and 208b. It is to be understood that clock lines carrying CLOCK 0, CLOCK 1, and CLOCK 2 signals are respectively communicatively coupled to each qubit-proximate latch, each intermediate latch, and each shift register-proximate latch. As such, all of superconducting circuits 200b can be operated synchronously.

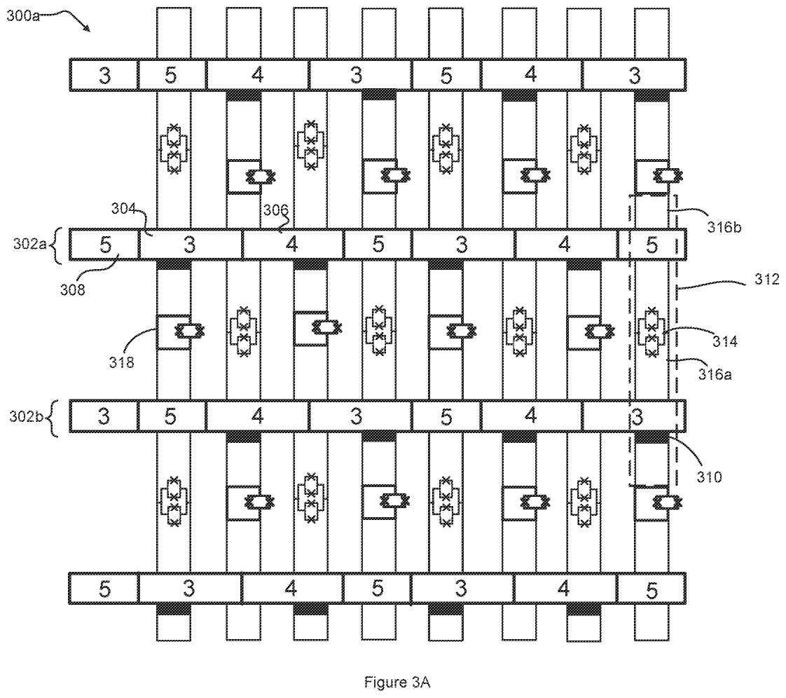

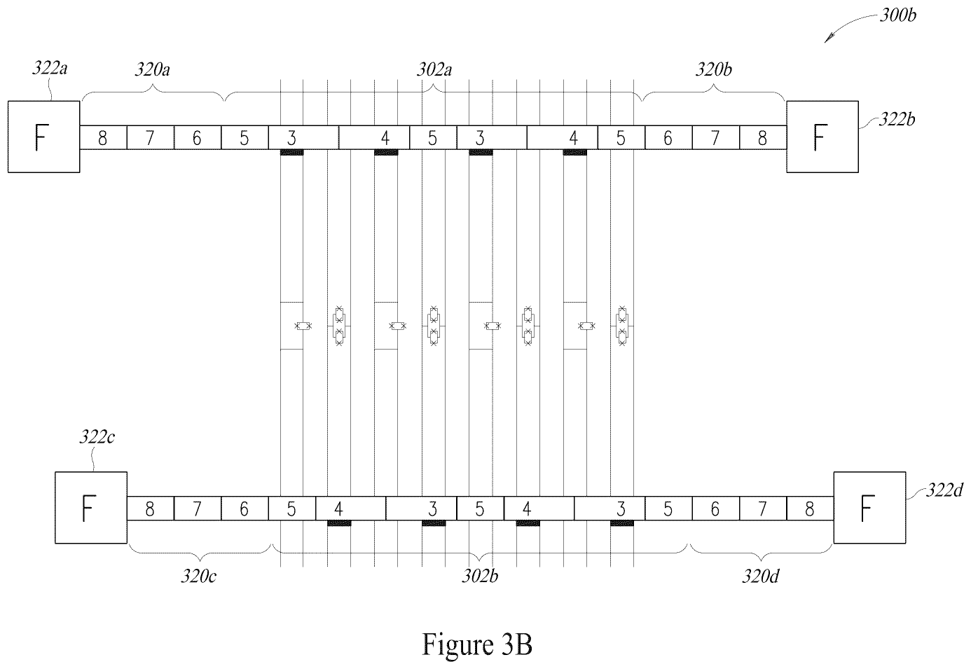

FIG. 3A is a schematic diagram of a portion of an example readout system for an example quantum processor, in accordance with the present systems and devices. Superconducting circuit 300a may be included as part of a readout control system for reading out qubit state information from a quantum processor. In some implementations, superconducting circuit 300a may be a portion of readout control system 126 (FIG. 1) used to read out qubit state information from quantum processor 120 of analog computer 104.

Superconducting circuit 300a comprises a first plurality of shift registers, four are shown although only a first shift register 302a and a second shift register 302b are called out. Each shift register of first plurality of shift registers 302a, 302b may be substantially parallel to one another, such that shift registers of first plurality of shift registers 302a,302b are parallel to along a major portion of their lengths. In other words, each shift register of first plurality of shift registers 302a, 302b are oriented in a first direction along a major portion of its length. Each shift register includes: a first set of shift register stages 304 (only one called out) that includes at least one shift register stage communicatively coupled to a clock line carrying a CLOCK 3 signal (labeled as ‘3’ in FIG. 3A); a second set of shift register stages 306 (only one called out) that includes at least one shift register stage communicatively coupled to a clock line carrying a CLOCK 4 signal (labeled as ‘4’); and a third set of shift register stages 308 (only one called out) that includes at least one shift register stage communicatively coupled to a clock line carrying a CLOCK 5 signal (labeled as ‘5’). Ones of shift register stages of first set of shift register stages 304, second set of shift register stages 306, and third set of shift register stages 308 are successively communicatively coupled to one another in series. In some implementations, shift register stages of first, second, and third sets of shift register stages 304, 306, 308 may be first, second, and third shift register stages 204, 206, 208 of superconducting circuit 200a (FIG. 2A) coupled to their respective clock lines or first, second, and third shift register stages 204b, 206b, 208b of superconducting circuit 200b (FIG. 2B) coupled to their respective clock lines.

Shift register stages of first set of shift register stages 304 and second set of shift register stages 306 are each communicatively coupled to a respective set of latches 310 (only one called out). In some implementations, each set of latches 310 includes a shift register-proximate latch, an intermediate latch, and a qubit-proximate latch, each communicatively coupled to a respective clock line carrying a CLOCK 2, CLOCK 1, and CLOCK 0 signal. In some implementation, set of latches 310 can be latches of first or second pluralities of latches 210a, 210b, 201c, 212a, 212b, 212c of superconducting circuit 200a coupled to their respective clock lines, or latches of first or second pluralities of latches 220a, 220b, 220c, 222a, 222b, 222c of superconducting circuit 200b coupled to their respective clock lines.

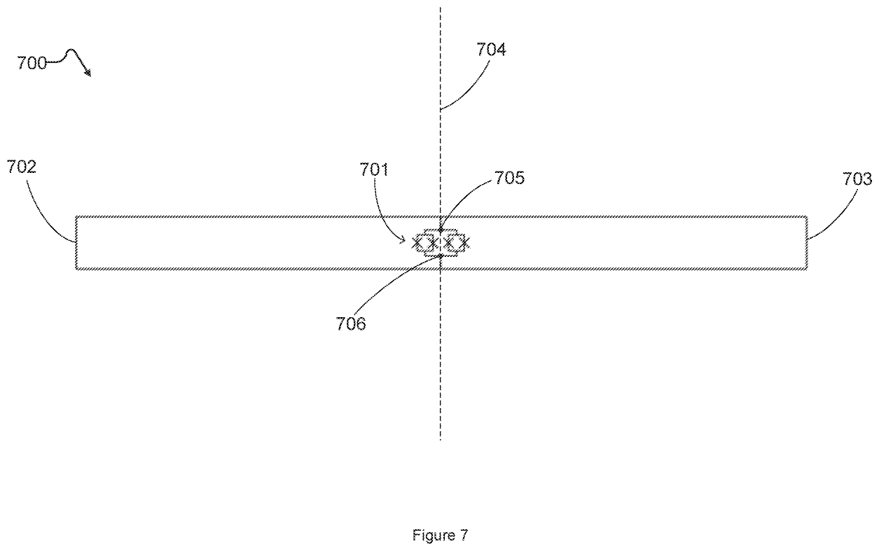

Shift register stages of first set of shift register stages 304 and second set of shift register stages 306 are each communicatively coupled to one qubit 312 (only one called out). In superconducting circuit 300a, each qubit 312 includes a first and a second superconducting loop 316a and 316b (collectively, 316) interrupted by a CCJJ 314. The multi-loop superconducting arrangement of qubit 312 will be described in further detail herein with respect to FIG. 7. Although a pair of shift registers 302 crosses each qubit 312 of superconducting circuit 300a, each qubit 312 is communicatively coupled to only one shift register, and one superconducting loop 316 of a respective qubit 312 is communicatively coupled to one shift register stage of the one shift register via a respective set of latches 310. Adjacent colinear qubits 312 are communicatively coupled to one another via couplers 318 (only one called out).

For instance, in FIG. 3A, qubit 312 is crossed by first shift register 302a and second shift register 302b. However, qubit state information of qubit 312 is only transmitted to second shift register 302b. Set of latches 310 is coupled to first superconducting loop 316a of qubit 312, which transmits the qubit state information to a shift register stage of first set of shift register stages 304 of second shift register 302b during operation of a readout system.

Although superconducting circuit 300a shows qubits 312 as multi-loop qubits, this is merely an example and is not intended to be limiting. In an alternative example, qubits 312 may be single-loop qubits, and the superconducting loop of each qubit may be communicatively coupled to a respective set of latches. In implementations where qubits 312 are multi-loop qubits, each qubit is crossed by at least two shift registers. For example, labeled qubit 312 of FIG. 3A is crossed by first shift register 302a and second shift register 302b. This arrangement advantageously provides symmetry in superconducting circuit 300a, which thereby reduces crosstalk between its elements.

However, only one superconducting loop 316a, 316b of each qubit 312 is required to be coupled to one shift register of first plurality of shift registers 302 to read out qubit state information, and each shift register does not require a shift register stage to load qubit state information corresponding to each crossed qubit. As such, the above-described coupling arrangement can reduce redundancy such that each shift register is coupled to only half an amount of qubits that it crosses, thereby reducing a number of shift register stages of each shift register in half Resultantly, superconducting circuit 300a can double a possible throughput of qubit state information as compared to a superconducting circuit with qubits coupled to each crossing shift register. Since a shift register including half as many shift register stages uses half as many shift operations to read out data, each pass can be performed in half the amount of time.

Although only four shift registers are illustrated (only two called out) in FIG. 3A as part of first plurality of shift registers, it is to be understood that any suitable number of shift registers of first plurality of shift registers 302a, 302b may be included as part of superconducting circuit 300a, based on a number of qubits in the quantum processor that cross first plurality of shift registers 302a, 302b at a non-zero angle (for example, the qubits can be oriented perpendicularly to first plurality of shift registers 302a, 302b). Non-zero in this sense means any value that is not an integer multiple of 360 degrees.

In some implementations, superconducting circuit 300a can also include a second plurality of shift registers (not shown in FIG. 3A). Shift registers of the second plurality of shift registers are arranged substantially in parallel with one another, such that shift registers of the second plurality of shift registers are parallel to one another along a major portion of their lengths. Shift registers of the second plurality of shift registers are also arranged to cross shift registers of first plurality of shift registers 302a, 302b at a non-zero angle. In other words, each shift register of the second plurality of shift registers are oriented in a second direction along a major portion of its length that is different from the first direction. In some implementations, shift registers of the second plurality of shift registers can be substantially perpendicularly to shift registers of first plurality of shift registers 302a, 302b.

Shift registers of the second plurality of shift registers can be used to measure and transmit qubit state information of qubits in the quantum processor that cross the second plurality of shift registers at a non-zero angle (for example, the qubits can be oriented perpendicularly to the second plurality of shift registers). Shift registers of the second plurality of shift registers can have the same structure as shift registers of first plurality of shift registers 302a, 302b, and can be communicatively coupled to perpendicularly oriented qubits in a manner analogous to communicative coupling of shift registers of first plurality of shift registers 302a, 302b to qubits 312.

FIG. 3B is a schematic diagram of an example readout system for an example quantum processor, which incorporates the portion of the example readout system of FIG. 3A and a plurality of readout interfaces 322a, 322b, 322c, 322d (four shown). Readout system 300b for a quantum processor includes at least superconducting circuit 300a, and may be included as part of a readout control system for reading out qubit state information from a quantum processor. In some implementations, readout system 300b may be all or a portion of readout control system 126 (FIG. 1) used to read out qubit state information from quantum processor 120 of analog computer 104.

Although readout system 300b of FIG. 3B only shows first and second shift registers 302a, 302b, it is to be understood that this is only an example portion of the full readout system, which may include any suitable number of shift registers of first plurality of shift registers 302a, 302b, based on a number of qubits in the quantum processor that cross first plurality of shift registers 302a, 302b at a non-zero angle.

Additionally, it is to be understood that readout system 300b can also include any suitable number of shift registers of a second plurality of shift registers that cross shift registers of first plurality of shift registers 302a, 302b at a non-zero angle, based on a number of qubits in the quantum processor that cross the second plurality of shift registers at a non-zero angle. A readout system including a first and a second plurality of shift registers enables all qubits in the quantum processor to be read out.

The portion of readout system 300b shown in FIG. 3B includes a plurality of qubits of the quantum processor, each of which are crossed by one or both of first and second shift registers 302a, 302b. Each of the illustrated shift register stages of first and second sets of shift register stages 304, 306 are communicatively coupled to one of the illustrated qubits via a respective set of latches 310 (FIG. 3A).

First and second shift registers 302a, 302b are communicatively coupled to a plurality of communication shift registers 320a, 320b, 320c, 320d (four shown). Both ends of first shift register 302a terminate with a shift register stage of third set of shift register stages 308 (FIG. 3A). One of the terminating shift register stages of shift register 302a is communicatively coupled to first communication shift register 320a and the other one of terminating shift register stages of shift register 302a is communicatively coupled to second communication shift register 320b. Similarly, both ends of second shift register 302b terminate with a shift register stage of third set of shift register stages 308. One of the terminating shift register stages of shift register 302b is communicatively coupled to third communication shift register 320c and the other one of terminating shift register stages of shift register 302b is communicatively coupled to fourth communication shift register 320d.

Communication shift registers 320a, 320b, 320c, 320d can comprise a plurality of shift register stages communicatively coupled in series with successive ones of one another. In some implementations, the shift register stages of communication shift registers 320a, 320b, 320c, 320d are QFPs. As can be seen in FIG. 3B, shift register stages of communication shift registers 320a, 320b, 320c, 320d are labeled as one of ‘6’, ‘7’, or ‘8’, respectively indicating a CLOCK 6, CLOCK 7, or CLOCK 8 signal carried by a respective communicatively coupled clock line that determines the operation of the shift register stage.

Each communication shift register 320a, 320b, 320c, 320d is coupled to one readout interface of plurality of readout interfaces 322. Qubit state information transmitted to first shift register 302a for readout operations is propagated along first shift register 302a and one of first or second communication shift registers 320a, 320b to be transmitted to a respective one of first or second readout interfaces 322a, 322b. Qubit state information transmitted to second shift register 302b for readout operations is propagated in a given direction through second shift register 302b and one of third or fourth communication shift registers 320c, 320d to be transmitted to a respective one of third or fourth readout interfaces 322c, 322d. Readout interfaces 322a, 322b, 322c, 322d can be used to transmit the qubit state information to a digital computer or another external device.

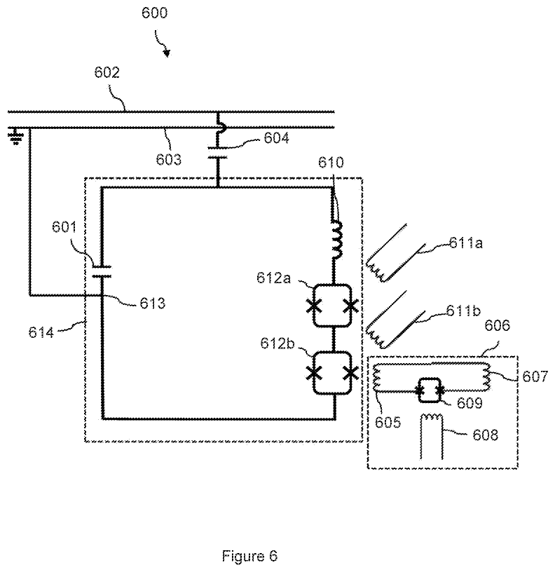

Any suitable combination of communication shift registers 320 and readout interfaces 322a, 322b, 322c, 322d can be incorporated as part of readout system 300b. In one implementation, readout interfaces 322a, 322b, 322c, 322d can be frequency and sensitivity tunable resonators (FASTRs). A description of a FASTR readout interfaces is included herein with respect to FIG. 6.

In certain implementations, it may be advantageous to provide a readout system that includes fewer readout interfaces 322a, 322b, 322c, 322d relative to the design of readout system 300b. For large-scale quantum processors, it may be preferable to reduce design complexity of a readout system that includes room-temperature electronics and superconducting resonators, in order to, for example: reduce a footprint of the readout system, use fewer resources, or reduce circuitry that may enable transmission of noise to noise-susceptible devices.

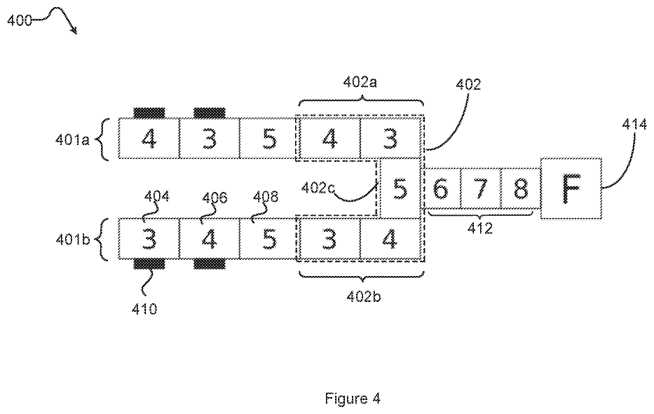

FIG. 4 is a schematic diagram of a portion of an example readout system for an example quantum processor in accordance with the present systems and devices. Superconducting circuit 400 connects neighboring buses to a readout interface, allowing for fewer readout interfaces per bus and reduced complexity of the readout system. Superconducting circuit 400 may be included as part of a readout control system for reading out qubit state information from a quantum processor. In some implementations, superconducting circuit 400 may be a portion of readout control system 126 (FIG. 1) used to read out qubit state information from quantum processor 120 of analog computer 104.

Superconducting circuit 400 is illustrated as including two readout shift registers: first readout shift register 401a and second readout shift register 401b. Each readout shift register 401a, 401b includes: at least one first shift register stage 404 coupled to a clock line carrying a CLOCK 3 signal (labeled as “3”, and only one called out); at least one second shift register stage 406 coupled to a clock line carrying a CLOCK 4 signal (labeled as “4”, and only one called out); and at least one third shift register stage 408 coupled to a clock line carrying a CLOCK 5 signal (labeled as “5”, and only one called out). First shift register stage 404, second shift register stage 406, and third shift register stage 408 are successively communicatively coupled to one another in series. In some implementations, first, second, and third shift register stages 404, 406, 408 may be first, second, and third shift register stages 204, 206, 208 (FIG. 2A) of superconducting circuit 200a coupled to their respective clock lines or first, second, and third shift register stages 204b, 206b, 208b (FIG. 2B) of superconducting circuit 200b coupled to their respective clock lines.

At least one first shift register stage 404 and at least one second shift register stage 406 of each of first readout shift register 401a and second readout shift register 401b are communicatively coupled to a respective readout chain 410 (only one called out). Each readout chain 410 includes: a set of latches, such as one of sets of latches 210a, 210b, 210c, 212a, 212b, 212c (FIG. 2A) or one of sets of latches 220a, 220b, 220c, 222a, 222b, 222c (FIG. 2B); clock lines carrying CLOCK 0, CLOCK 1, and CLOCK 2 signals, each coupled to one latch of the set of latches; and, a qubit, such as one of qubits 202a, 202b, respectively coupled to the set of latches.

Third shift register stages 408 of first and second readout shift registers 401a, 401b are operable as spacing stages that exclusively perform shift operations.

First and second readout shift registers 401a and 401b are communicatively coupled to one another via a shared interstitial bus 402. The broken lines included in FIG. 4 show the approximate outline of interstitial bus 402 and are for illustrative purposes only. Interstitial bus 402 comprises a plurality of first, second, and third shift register stages 404, 406, 408 communicatively coupled in series with successive ones of one another. A terminating third shift register stage 408 of first and second readout shift registers 401a, 401b can each be respectively coupled to a first and a second interstitial shift register stage pair 402a, 402b of interstitial bus 402. Each interstitial shift register stage pair 402a, 402b comprises first and second shift register stages 404, 406 successively coupled in series. First and second interstitial shift register stage pairs 402a, 402b are coupled to one another via a connecting third shift register stage 402c of interstitial bus 402, thus communicatively coupling first and second readout shift registers 401a and 401b to one another. In one implementation, the shift register elements of interstitial bus 402 are QFPs.

Interstitial bus 402 is also communicatively coupled to a communication shift register 412. Communication shift register 412 includes a plurality of shift register stages. Connecting third shift register stage 402c of interstitial bus 402 can be communicatively coupled to a first terminating shift register stage of communication shift register 412. In some implementations, the shift register stages of communication shift register 412 are QFPs. Each one of shift register stages of communication shift register 412 can be communicatively coupled to a corresponding clock line carrying one of a CLOCK 6, CLOCK 7, or CLOCK 8 signal, and respective latching and suppression clock signals can be used to propagate qubit state information along communication shift register 412.

Communication shift register 412 is communicatively coupled to a readout interface 414. In some implementations, readout interface 414 may comprise at least one FASTR, which is described later herein with respect to FIG. 6.

In an example operation, superconducting circuit 400 can be used to transmit qubit state information of a qubit that is part of called out readout chain 410. Qubit state information can be read out from each one of first readout shift register 401a and second readout shift register 401b using two passes, as described above with respect to FIG. 2A.

A first pass or second pass of reading out superconducting circuit 400 can include transmitting qubit state information of the qubit of called out readout chain 410 to called out first shift register stage 404 of second readout shift register 401b. During the subsequent stepwise “shift” operations of the pass, qubit state information is propagated along second readout shift register 401b, across called out second and third shift register stages 406 and 408, and then into interstitial bus 402. Once the qubit state information is in connecting third shift register stage 402c of interstitial bus 402, the qubit state information can be transmitted along communication shift register 412 to a selected readout interface 414. Additionally, or alternatively, the first and/or the second pass can include shifting the qubit state information to first interstitial shift register stage pair 402b and cycling the qubit state information in a counterclockwise direction through shift register stages of first readout shift register 401a.

In some implementations, one or more of superconducting circuit 400 can be used to connect pairs of nearest-neighbor readout shift registers to one another, thereby enabling readout of a larger number of qubits in a quantum processor.

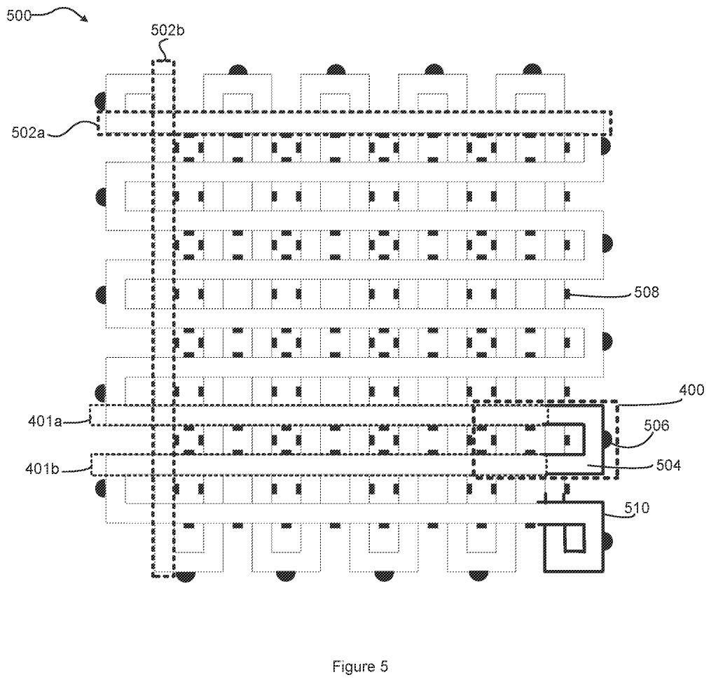

FIG. 5 illustrates example full-processor readout system, which incorporates the example portion of the example readout system of FIG. 4. Readout system 500 includes a plurality of superconducting circuits 400 to connect readout shift registers that read out qubit state information across an entire quantum processor. Readout system 500 may be included as part of a readout control system for reading out qubit state information from a quantum processor. In some implementations, readout system 500 may be all or a portion of readout control system 126 (FIG. 1) used to read out qubit state information from quantum processor 120 of analog computer 104.

Readout system 500 includes a first plurality of readout shift registers 502a (only one called out). Each readout shift registers of the first plurality of readout shift registers 502a are substantially parallel to one another and oriented in a first direction, such that shift registers of first plurality of shift registers 302 are parallel to one another along a major portion of their lengths in the first direction. Readout system 500 also includes a second plurality of readout shift registers 502b (only one called out), which are substantially parallel to one another and oriented in a second direction that is different than the first direction. As such, shift registers of second plurality of shift registers 502b are parallel to one another along a major portion of their lengths in the second direction. In some implementations, the second direction is perpendicular to the first direction.

Each readout shift register of first and second pluralities of readout shift registers 502a, 502b includes first, second, and third sets of shift register stages (and their correspondingly coupled clock lines) that are successively coupled to ones of another. In some implementations, each readout shift register of first and second pluralities of readout shift registers 502a, 502b can be one of first and second readout shift registers 401a, 401b (FIG. 4). In some implementations, each readout shift register can include more shift register stages than first and second readout shift registers 401a, 401b, thereby having a longer length.

Each readout shift register of first and second pluralities of readout shift registers 502a, 502b includes a plurality of readout chains 508 (only one called out). Each readout chain 508 communicatively couples one qubit in the quantum processor to one shift register stage of one readout shift register 502a or 502b. Each readout chain 508 can communicatively couple the qubit to the readout shift register via a respective set of latches and their correspondingly coupled clock lines. In some implementations, each readout chain 508 can be: readout chain 410 of superconducting circuit 400 (FIG. 4); or first or second plurality of latches 210a, 210b, 210c or 212a, 212b, 212c (FIG. 2A) coupled to a respective one of first or second qubit 202a or 202b; or first or second plurality of latches 220a, 220b, 220c or 222a, 222b, 222c (FIG. 2B) coupled to a respective one of first or second qubit 202a or 202b.

Pairs of shift registers of first plurality of readout shift registers 502a can be communicatively coupled to one another by the structure of superconducting circuit 400. In FIG. 5, only one superconducting circuit 400 is called out, and its elements are delineated by a broken box for illustrative purposes only.

In FIG. 5, first readout shift register 401a and second readout shift register 401b of superconducting circuit 400 are called out, and are collectively a nearest-neighbor pair of readout shift registers of first plurality of shift registers 502a. In other words, of shift registers of first plurality of shift registers 502a, first readout shift register 401a is one of the shift registers in closest proximity to second readout shift register 401b. As well, second readout shift register 401b is part of a second nearest-neighbor pair of readout shift registers with the shift register of first plurality of shift registers 502a in closest proximity on a side of second readout shift register 401b that opposes first readout shift register 401a.

Each pair of nearest-neighbor shift registers of first plurality of readout shift registers 502a are communicatively coupled by a respective interstitial bus 504 (only one called out, and delineated with bolded lines). Each interstitial bus 504 is comprised of shift register stages, and in some implementations can be interstitial bus 402. Each interstitial bus 504 is communicatively coupled to a respective readout interface chain 506 (only one called out). Each readout interface chain 506 can include a readout interface communicatively coupled to interstitial bus 504 via a communication shift register. In some implementations, each readout chain 506 can comprise communication chain 412 and readout interface 414 of superconducting circuit 400 of FIG. 4.

Pairs of nearest-neighbor shift registers of second plurality of readout shift registers 502b can be communicatively coupled to one another by the structure of superconducting circuit 400 in a similar manner to coupling of nearest-neighbor pairs of first plurality of readout shift registers 502a described above.

In readout system 500, first plurality of readout shift registers 502a are also communicatively coupled to second plurality of readout shift registers 502b by two corner connection buses 510 (only one called out). Corner connection buses 510 are similar to interstitial buses 504, but instead of coupling two nearest-neighbor shift registers of belonging to a same plurality of readout shift registers, corner connection buses couple a terminating shift register of first plurality of readout shift registers 502a with a terminating shift register of second plurality of readout shift registers 502b.

As all shift registers in first plurality of readout shift registers 502a are successively coupled to one another, and all shift registers in second plurality of readout shift registers 502b are successively coupled to one another, corner connection buses 510 communicatively couple all shift registers in readout system 500 to one another. The resultant arrangement is a grid of buses that connect to one another in a serpentine arrangement. In some implementations, first and second pluralities of shift registers 502a, 502b and the connecting buses therebetween (i.e., interstitial buses 504 and corner connecting buses 510) can be viewed as a single, cyclical shift register.

Due to the communicative coupling of all shift registers in readout system 500, qubit state information of any qubit in the quantum processor oriented in either the first or the second direction can be transmitted to any shift register stage in first and second pluralities of readout shift registers 502a, 502b and/or can be read out by any one of readout interface chains 506.

The superconducting circuits and readout systems described herein can perform readout of qubit state information using two passes, and include: one or more shift registers having shift register stages of a first and a second set of shift register stages that are each coupled to a respective qubit, and a third set of shift register stages that are operable as spacing stages. This arrangement may be advantageous over alternative readout systems, or portions of readout systems, that include qubits coupled to first, second, and third sets of shift register stages. The superconducting circuits and readout systems herein can require fewer components when compared to these alternative readout systems, and thus have a reduced complexity, footprint, and cost.

In such an alternative readout system, a pair of a shift registers arranged perpendicularly to one another (for example, such as one shift register of first plurality of shift registers 502a and one as one shift register of second plurality of shift registers 502b as shown in FIG. 5) may be designed to have “crossover stages”, each of which includes an intermediate shift register stage and corresponding clock line. The crossover stages provide redundancy in the shift register to insulate from information loss arising from a failed shift register stage. The same effects can be realized using the arrangement of shift register stages of the shift registers described herein, in which shift register stages of the third plurality of shift register stages allow for tolerance of a failed stage within a shift register. Since shift registers stages of the third plurality of shift register stages are not coupled to qubits via sets of latches, these shift register stages can provide redundancy without impacting the ability of a shift register to obtain desired qubit state information.

Due to the lack of crossover stages, the arrangements described herein can advantageously perform readout more quickly than the above-described alternative readout systems. A width N of a quantum processor can be defined as a number of columns of qubits in the quantum processor, and a height M of the quantum processor can be defined as a number of rows of qubits in the quantum processor. To read out qubit state information from a quantum processor having width N using the above-described alternative readout system, each readout shift register will include 1.2N shift register stages. Conversely, to read out qubit state information from a quantum processor having width N using the arrangements described herein, each readout shift register includes only 0.75N shift register stages. As such, readout of a single qubit using the arrangements described herein can be performed in 0.625 of the time that may be needed to perform readout using the above-described alternative readout system.

When considering reading out qubit state information from all qubits of a quantum processor having width N, the reduction in performance time using the arrangements described herein becomes more pronounced. As the above-described alternative readout systems read out all qubit state information in three passes, performing full read-out includes transmitting information through 3-1.2N=3.6N shift register stages. As the arrangements described herein read out all qubit state information in two passes, the full read-out transmits information through 2-0.75N=1.5N shift register stages. As such, full readout of a quantum processor using the arrangements described herein can be performed in 0.417 of the time that may be needed to perform readout using the above-described alternative readout system.

### Example FASTR Readout Interface

A frequency and sensitivity tunable resonator (FASTR) is a detector or readout interface comprising a superconducting resonator having intrinsic frequency-domain multiplexing capabilities. An array of FASTRs may be used to read out qubit state information of a plurality of qubits in a quantum processor. The design of the FASTR enables compensation of fabrication imperfections through independent tuning of resonator parameters, allowing for efficient use of device bandwidth. As a result, an array of FASTRs can exhibit homogeneous sensitivity and uniform frequency spacing. Decoupling the tuning of resonator sensitivity allows for efficient packing to be achieved for a fixed device bandwidth, as it limits the frequency shifting of each resonator in a FASTR array. More detail directed to FASTR detectors can be found in “A frequency and sensitivity tunable micro-resonator array for high-speed quantum processor readout” (Whittaker et al., 2016) and U.S. Pat. No. 10,938,346.

FIG. 6 is a schematic diagram of a superconducting circuit 600 comprising a FASTR. Superconducting circuit 600 can be employed as readout interfaces 322 and 414 in the example readout systems of FIGS. 3B and 4.

Superconducting circuit 600 comprises a superconducting resonator 614 with first and second superconducting quantum interference devices (SQUID) loops 612a and 612b, which operate as tunable non-linear inductors that are able to independently tune the resonator frequency and sensitivity. Each one of first and second SQUID loops 612a and 612b is a DC SQUID. Each DC SQUID comprises a superconducting loop, and a pair of Josephson junctions (illustrated by crosses X) arranged on the superconducting loop in parallel with one another. First and second SQUID loops 612a and 612b advantageously enable independent tuning of the resonance frequency and the sensitivity of superconducting resonator 614 by adjusting a flux bias in first and second SQUID loops 612a and 612b.

Superconducting resonator 614 further comprises a capacitance 601 and an inductance 610. First and second SQUID loops 612a and 612b are arranged in series with inductance 610, and are arranged in parallel with capacitance 601. In one implementation, inductance 610 can be a niobium spiral inductor. In one implementation, capacitance 601 can be a parallel plate capacitor. However, these are merely examples, and any suitable components may be employed.

First and second interfaces 611a and 611b inductively couple a flux bias to first and second SQUID loops 612a and 612b, respectively. Once a suitable operating point has been found, the flux biases provided by first and second interfaces 611a and 611b can be static. This advantageously allows superconducting circuit 600 to require only a small number of wires or conductive traces to program an array of flux DACs, as the tunable first and second SQUID loops 612a and 612b do not need an independent analog control line for each superconducting resonator 614.

Superconducting circuit 600 further comprises a transmission line 602 with a grounded line 603, a coupling capacitance 604, and a last or final shift register stage 606. Last shift register stage 606 comprises first and second inductive interfaces 605 and 607, SQUID loop 609, and interface 608. Last or final shift register stage 606 may, for example, take the form of a Quantum Flux Parametron (QFP). Last or final shift register stage 606 is the endpoint of a shift register comprising one or more stages. Last or final shift register stage 606 is a stage that can be communicatively coupled to superconducting resonator 614 for the purposes of reading out the state of a superconducting device. In one implementation, superconducting resonator is fed by a flux shift register which, in turn, is fed by a flux qubit.

### Example Superconducting Flux Qubits

The design and selection of a topology of a quantum processor—that is, the arrangement defining the interconnection of qubits and couplers and/or other quantum devices—is an important aspect of quantum processor design. Particular topologies may be better suited to solving certain classes of problems than others. Various examples of quantum processor topologies are described in detail in: U.S. Pat. Nos. 7,533,068; 8,772,759, 9,170,278; and 9,178,154; U.S. Patent Application Publication No. 2019/0220771; and International Patent Application PCT/US22/38498.

Some quantum processor topologies include a repeated lattice of sub-topologies (also referred to as “cells” or “unit cells”) that comprise at least portions of qubits and couplers. In the topology described in U.S. Provisional Patent Application No. 63/227,395, a qubit may be included in multiple cells and a coupler may be shared among multiple cells. In such a topology, it may be advantageous for the physical qubits to have multiple superconducting loops, such that multiple cells sharing a particular qubit can include at least one superconducting loop of the qubit.

Superconducting circuits 200a, 200b, 200c, 300a, 400 and readout systems 300b and 500 described above can be used to readout qubit state information from a variety of quantum processor topologies, including quantum processor topologies that include qubits with multiple superconducting loops. Use of these superconducting circuits and readout systems can advantageously reduce a number of shift register stages and a readout time required to read out qubit state information from such topologies.

For instance, superconducting circuit 300a and readout system 300b of FIGS. 3A and 3B are illustrated such that plurality of qubits 312 to be read out have multiple superconducting loops. Called out qubit 312 has first superconducting loop 316a and second superconducting loop 316b, each of which cross one of shift registers 302b, 302a to provide a symmetrical readout system design. However, since reading out the qubit state information can be achieved by coupling only one of superconducting loops 316 to one crossing shift register of first plurality of shift registers 302, a length of each shift register can be reduced by not coupling the other one of superconducting loops 316 to the other crossing shift register of first plurality of shift registers 302. With only half of the number of qubits crossing each shift register being coupled to that shift register, each shift register can include fewer shift register stages. Thus, fewer shift operations, and consequently less time, is required to read out qubit state information of qubits having multiple superconducting loops.

FIG. 7 is a schematic diagram of an example superconducting flux qubit 700, which can optionally be employed in the example superconducting circuits of FIGS. 2A-C, 3A, and 4 and the example readout systems of FIGS. 3B and 5.

Superconducting flux qubit 700 includes a loop of superconducting material interrupted by a Josephson junction. The superconducting material may be a material that exhibits superconducting behavior at and below a critical temperature that is inherent to the material. In some implementations, it may be beneficial to provide a multi-loop flux qubit, which may allow for increased connectivity between qubits and thus influence the type and complexity of problems that may be solved by the quantum processor.

In the example implementation of FIG. 7, superconducting flux qubit 700 comprises a compound-compound Josephson junction (CCJJ) 701. In another implementation, superconducting flux qubit 700 may comprise a Josephson junction that is a compound Josephson junction (CJJ).

In the illustrated implementation, a first qubit loop 702 is formed by a first superconducting current path, and a second qubit loop 703 is formed by a second superconducting current path. First qubit loop 702 and second qubit loop 703 are electrically coupled in parallel across CCJJ 701. In the example implementation of FIG. 7, first qubit loop 702 and second qubit loop 703 are substantially symmetric about an axis 704 of CCJJ 701. Axis 704 intersects a first connection point 705 between first and second qubit loops 702, 703 and CCJJ 701. Axis 704 also intersects a second connection point 706 between first and second qubit loops 702, 702 and CCJJ 701.

The example qubit shown in FIG. 7 is not intended to be limiting. In other implementations, example readout systems may include qubits of another type (e.g., single loop flux qubits).

### Methods of Performing Readout

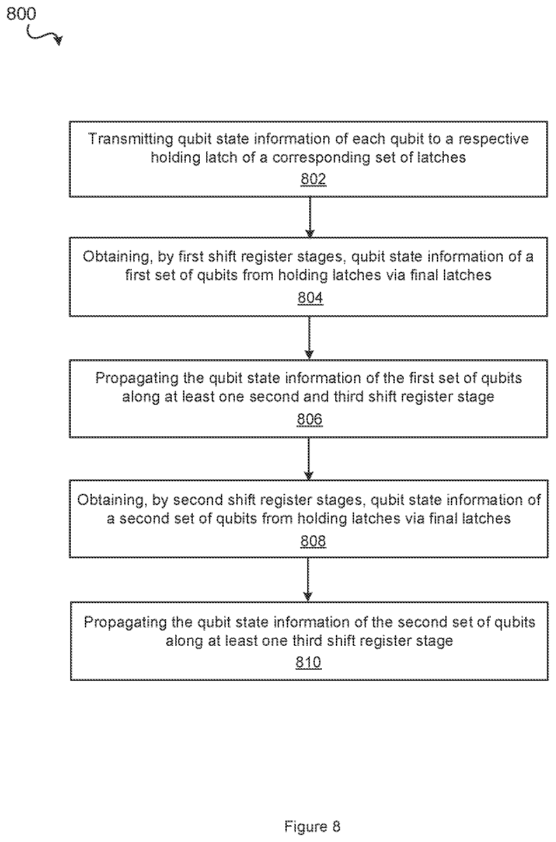

FIG. 8 is a flowchart of an example method 800 of transmitting qubit state information in a quantum processor. In some implementations, method 800 may be performed by hybrid computing system 100 (FIG. 1). Qubit state information can be obtained from quantum processor 120 of analog computer 104 via qubit control system 122. In some implementations, readout control system 126 can include any one of superconducting circuit 200a, 200b, 200c, 300a, and 400 and readout system 300b and 500. In some implementations, method 800 is performed by instructing analog computer 104 to perform operations based on execution of a program stored in system memory 110 by digital processor 106 via controller 114.

In some implementations, digital processor 106 can provide one or more signals to one or more digital-to-analog converters (DACs) and/or other structures that are part of readout control system 126. The one or more DACs can be used at least to generate control signals for performing operations related to the acts of method 800, such as generating clock signals that determine the latching behavior of shift register stages and latches.

Method 800 can be used to read out qubit state information from any one of superconducting circuit 200a, 200b, 200c, 300a, and 400 and readout system 300b and 500.

Qubit state information can be a binary value (expressed, for example, as: “−1” and “1,”, or “0” and “1,”, or “spin-up” and “spin-down”) that is representative of part of a solution to a problem solved via quantum computation or a quantum-generated sample. The binary qubit state information can be represented digitally by a signal based on discrete magnetic flux quanta.

In some implementations where a quantum processor performs quantum annealing and/or adiabatic quantum computing, qubit state information may be read out following quantum evolution of qubits from a first state to a second state.

At 802, qubit state information of each qubit is transmitted to a respective holding latch of a corresponding set of latches. The plurality of qubits includes a first set of qubits and a second set of qubits. Each set of latches is communicatively coupled to at least one shift register, which includes: a first set of shift register stages, a second set of shift register stages, and a third set of shift register stages. Each qubit of the first set of qubits is communicatively coupled to a respective shift register stage of the set of first shift register stages via a set of latches. Each qubit of the second set of qubits is communicatively coupled to a respective shift register stage of the set of second shift register stages via a set of latches.

In an example involving readout using superconducting circuit 200a of FIG. 2A, qubit state information is read out from first qubit 202a and second qubit 202b. In some implementations, first and second qubits 202a, 202b are superconducting flux qubit 700 of FIG. 7 having multiple superconducting loops 702, 703. First qubit 202a can belong to the first plurality of qubits, which is communicatively coupled to first shift register stage 204 via first set of latches 210a, 210b, 210c. Second qubit 202b can belong to the second plurality of qubits, which is communicatively coupled to second shift register stage 206 via second set of latches 212a, 212b, 212c. A holding latch of first set of latches 210a, 210b, 210c can be intermediate latch 210b, and a holding latch of second set of latches 212a, 212b, 212c can be intermediate latch 212b.

Transmitting qubit state information from a qubit to a respective holding latch of a corresponding set of latches can include applying clock signals to clock lines coupled to particular latches of each set of latches.

First, qubit state information is transmitted from first and second qubits 202a, 202b to first and second qubit-proximate latches 210c, 212c on coupling to a first latch clock signal, which can be a CLOCK 0 latching signal. The CLOCK 0 latching signal can simultaneously be applied to first and second qubit-proximate latches 210c, 212c by coupling the clock signal to a respective Josephson junction of each qubit-proximate latch 210c, 212c via respective interfaces of the clock line. When this CLOCK 0 latching signal is received, first and second qubit-proximate latches 210c, 212c: load a signal representing qubit state information of first and second qubits 202a and 202b, retain the signal despite perturbations or evolutions in the source signal, and continuously output the signal until the CLOCK 0 signal transitions from a CLOCK 0 latching signal to a CLOCK 0 suppressing signal

Subsequently, qubit state information is shifted from first and second qubit-proximate latches 210c, 212c to intermediate latches 210b, 212b via a holding latch clock signal, which can be a CLOCK 1 signal. The CLOCK 1 latching signal can simultaneously be applied to first and second intermediate latches 210b, 212b by coupling the clock signal to a respective Josephson junction of each intermediate latch 210b, 212b via respective interfaces of the clock line. When the CLOCK 1 latching signal is received, first and second intermediate latches 210b, 212b are latched to hold qubit state information.

In implementations where each set of latches includes more than one latch between the first latch and a final latch, act 802 can also include applying one or more intermediate latch latching clock signals and subsequently one or more intermediate latch suppression clock signals to a Josephson junction of each one or more intermediate latches of each set of latches. In doing so, qubit state information is transmitted through each intermediate latch before a holding latch latching clock signal latches the qubit state data in the holding latches.

Acts 804 and 806 describe part of a first pass of reading out from the quantum processor, which includes reading out qubit state information of the first set of qubits. Acts 808 and 810 describe part of a second pass of reading out from the quantum processor, which includes reading out qubit state information of the second set of qubits. The acts of method 800 result in a two-pass full-processor readout.

At 804, each shift register stage of the first set of shift register stages obtains qubit state information of each qubit of the first set of qubits from a respective holding latch via a respective final latch.

To achieve this, qubit state information of each qubit of the plurality of qubits that is stored in a respective holding latch can be loaded into a respective final latch of each set of latches. Afterwards, the qubit state information of each qubit of the first set of qubits can be shifted from a respective final latch to a respective shift register stage of the first set of shift register stages.

For example, in superconducting circuit 200a, qubit state information of first and second qubits 202a, 202b is transmitted from first and second intermediate latches 210b, 212b to first and second shift register-proximate latches 210a, 212a based on coupling of a CLOCK 2 latching signal to first and second shift register-proximate latches 210a, 212a. The qubit state information of first qubit 202a in first shift register-proximate latch 210a is then shifted to first shift register stage 204. The shifting occurs when a first clock signal, such as a CLOCK 3 latching signal, is coupled into Josephson junction 204c of first shift register stage 204 via a first clock line interface 214a, and a CLOCK 2 suppression signal is coupled to first and second shift register-proximate latches 210a, 212a to suppress the qubit state information that was previously stored therein.

In implementations including more than one shift register stage in the first set of shift register stages, first clock signals (including first latching and first suppression clock signals) can be periodic signals such that the qubit state information of all qubits of the first plurality of qubits can be shifted to the first set of shift registers at once (e.g., concurrently or even simultaneously).

At 806, the qubit state information of the first set of qubits is propagated along at least one shift register stage of the second set of shift register stages and at least one shift register stage of the third set of shift register stages to read out the qubit state information of the first set of qubits.

In implementations where each of first, second, and third sets of shift register stages includes only one shift register stage, such as in superconducting circuit 200a of FIG. 2A, qubit state information of the first plurality of qubits is shifted through one second shift register stage and one third shift register stage. For example, qubit state information of first qubit 202a is shifted from first shift register stage 204 to second shift register stage 206 when second shift register stage 206 is latched based on receipt of a CLOCK 4 latching signal via its Josephson junction, and a CLOCK 3 suppression signal is coupled to first shift register stage 204. The qubit state information is then shifted from second shift register stage 206 to third shift register stage 208 when third shift register stage 208 is latched based on receipt of a CLOCK 5 latching signal via its Josephson junction, and a CLOCK 4 suppression signal is coupled to second shift register stage 206. In other implementations, qubit state information can be shifted along shift register stages in an opposing direction, for example to read out from a different readout interface, by applying a third latching clock signal to third shift register stage 208 and a first suppression clock signal to first shift register stage 204 followed by a second latching clock signal to second shift register stage 206 and a third suppression clock signal to third shift register stage 208.

In implementations where each of first, second, and third sets of shift register stages includes a plurality of shift register stages, such as in superconducting circuits 200b and 300a of FIGS. 2C and 3A, qubit state information can be shifted through alternating ones of shift register stages of each plurality of shift register stages.

Information can be shifted in a first direction along shift register stages of the second, the third, and the first sets of shift register stages until reaching a terminating shift register stage by alternating ones of second, third, and first latching clock signals and suppression clock signals.

Alternatively, information can be shifted in a second direction along shift register stages of the third, the second, and the first sets of shift register stages until reaching a terminating shift register stage by alternating ones of third, second, and first latching clock signals and suppression clock signals.

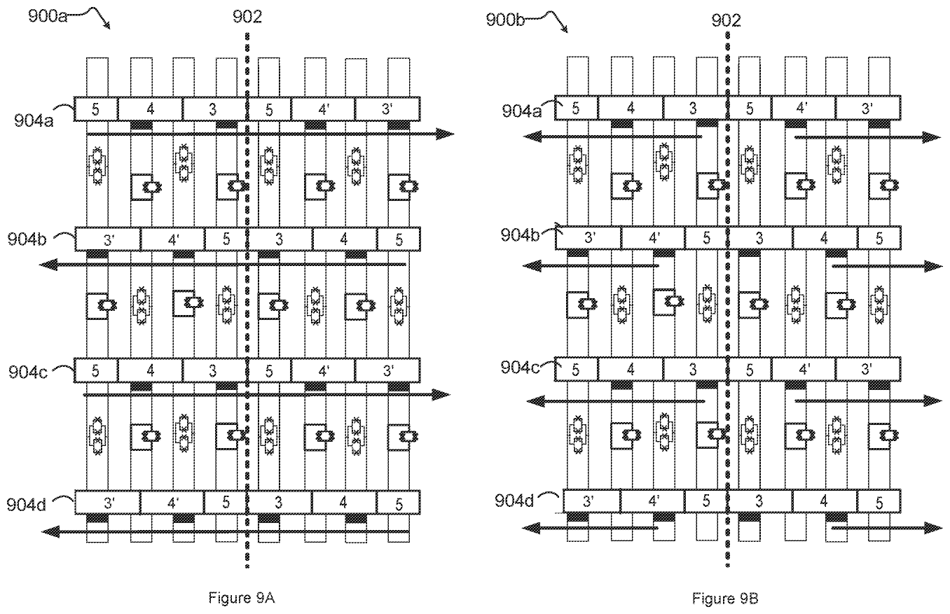

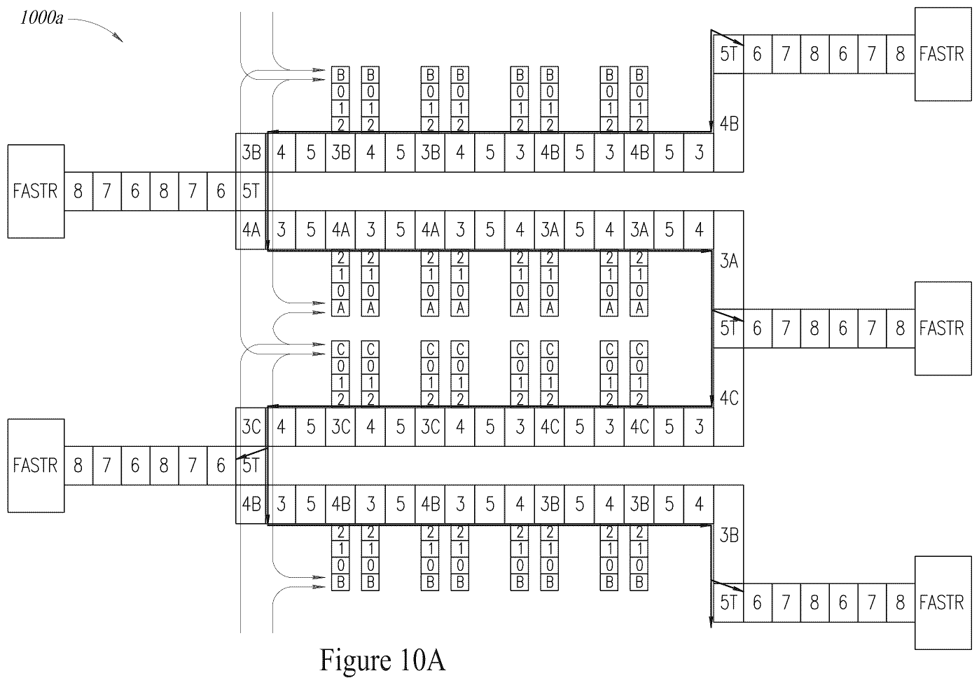

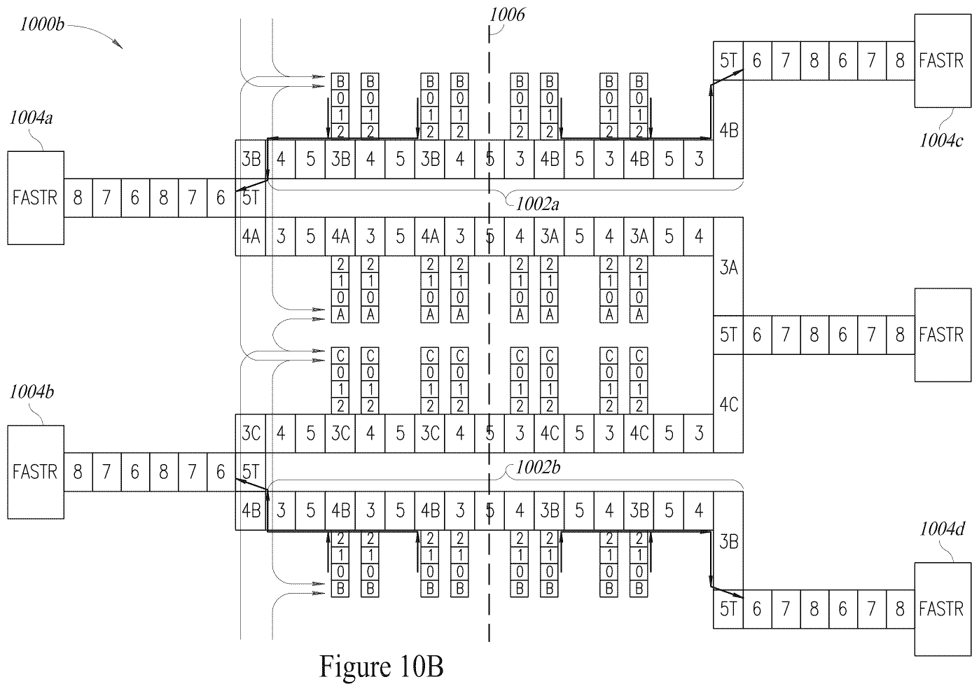

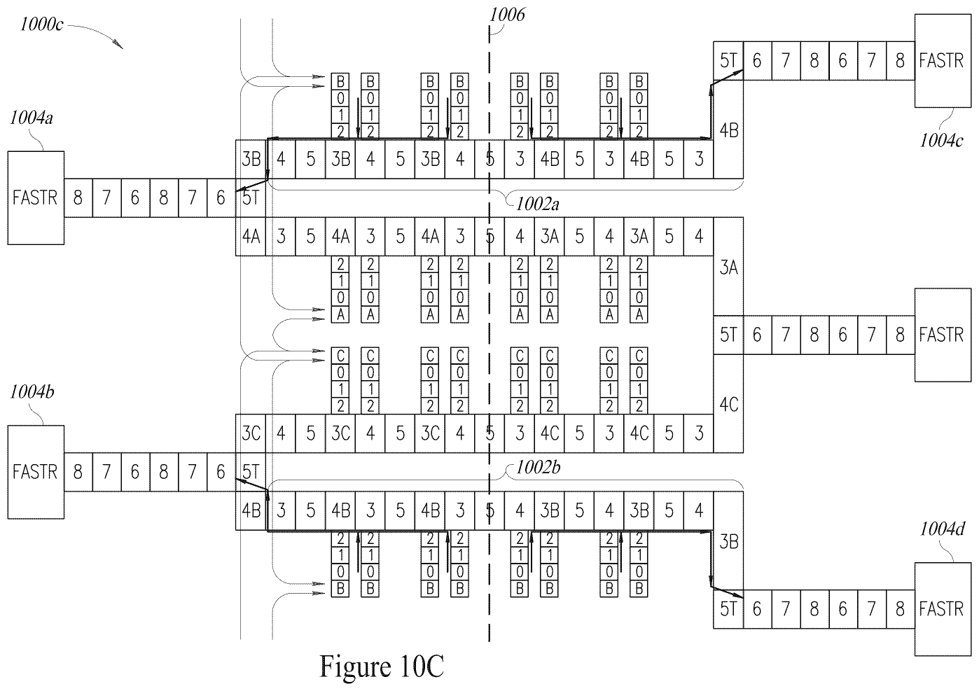

As an example, a direction of shifting can be determined by a relative location of a readout interface designated to read out the qubit state information. A direction of shifting can be application-dependent, such as described below with respect to FIGS. 9A, 9B, 10A, 10B, and 10C.

In some implementations, all shift register stages of a same shift register are provided with clock signals to shift qubit state information in a same direction to be read out by a same readout interface (see, for example, the description of FIGS. 9A and 10A below). In other implementations, shift register stages of a same shift register are provided with clock signals to shift qubit state information in different directions to be read out by different readout interfaces, for instance, reduce operation time (see, for example, the description of FIGS. 9B, 10B, and 10C below).

Alternatively and/or additionally, a direction of shifting can be selected to avoid use of faulty components in a system. For example, in readout system 300b, first shift register 302a may shift qubit state information in a first direction to be read out using first readout interface 322a; however, if first readout interface 322a were to fail or become corrupted, readout system 300b may be operated to shift qubit state information along first shift register 302a in a second direction to be read out using second readout interface 322b. By selecting a shifting direction of qubit state information, redundancies in the design of the superconducting circuits and readout systems herein can be leveraged for robust system operation.

In implementations where more than one qubit of the first plurality of qubits is coupled to a respective shift register stage of the first set of shift register stages, qubit state information of all qubits of the first plurality of qubits are synchronously propagated along the shift register.

In some implementations, reading out the qubit state information of the first set of qubits further includes propagating qubit state information of qubits of the first set of qubits along at least one communication shift register, and shifting the qubit state information to at least one readout interface.

For example, in readout system 300b, qubit state data of a qubit coupled to first shift register stage 304 can be propagated along first shift register 302a by alternating first, second, and third latching clock signals and suppression clock signals. Then, the qubit state data can be propagated along second communication shift register 320b by latching and suppressing its shift register stages using fourth, fifth, and sixth clock signals. The latching and suppression operations of shift register stages of communication shift registers are performed currently or even simultaneously with the cycling of qubit state information through the readout shift registers. Afterwards, the qubit state data can be shifted to second readout interface 322b. Second readout interface 322b can be a FASTR readout interface, as shown by superconducting circuit 600 in FIG. 6, and the last shift register stage of second communication shift register 320b can be last or final shift register stage 606. The qubit state information can be transmitted to a superconducting resonator 614 by coupling the flux quanta representing the state across second inductive interface 605 of last or final shift register stage 606 and second SQUID loop 612b. The signal can be carried to an additional structure or device by transmission line 602.

At 808, each shift register stage of the second set of shift register stages obtains qubit state information of the second set of qubits from a respective holding latch via a respective final latch.

To achieve this, qubit state information of each qubit of the plurality of qubits can be shifted from a respective holding latch to a respective final latch of each set of latches. Afterwards, the qubit state information of each qubit of the second set of qubits can be shifted from a respective final latch to a respective shift register stage of the second set of shift register stages.

For example, in superconducting circuit 200a, qubit state information of first and second qubits 202a, 202b is shifted from first and second intermediate latches 210b, 212b to first and second shift register-proximate latches 210a, 212a. This can include latching first and second shift register-proximate latches 210a, 212a based on a final latch clock signal, such as a CLOCK 2 latching signal. The final latch clock signal can be coupled to respective Josephson junctions of first and second shift register-proximate latches 210a, 212a via latch clock line interface 214d, and a CLOCK 1 suppression signal is coupled to first and second intermediate latches 210b, 212b to suppress the qubit state information that was previously stored therein.

Subsequently, the qubit state information of second qubit 202b in second shift register-proximate latch 212a is then shifted to second shift register stage 206. The shifting occurs when a second clock signal, such as a CLOCK 4 latching signal, is coupled into Josephson junction of second shift register stage 204 via a second clock line interface 214b, and a CLOCK 2 suppression signal is coupled to first and second shift register-proximate latches 210a, 212a to suppress the qubit state information that was previously stored therein.

In implementations including more than one shift register stage in the second set of shift register stages, second clock signals (including second latching and second suppression clock signals) can be periodic signals such that the qubit state information of all qubits of the second plurality of qubits can be shifted to the second set of shift registers at once.

At 810, the qubit state information of the second set of qubits is propagated along at least one shift register stage of the third set of shift register stages to read out the qubit state information of the second set of qubits.

In implementations where each of first, second, and third sets of shift register stages includes only one shift register stage, such as in superconducting circuit 200a of FIG. 2A, qubit state information of the second plurality of qubits is shifted through at least one third shift register stage. For example, qubit state information of second qubit 202b is shifted from second shift register stage 206 to third shift register stage 208 when third shift register stage 208 is latched based on receipt of a CLOCK 5 latching signal via its Josephson junction, and a CLOCK 4 suppression signal is coupled to second shift register stage 206. In other implementations, qubit state information can be shifted along shift register stages in an opposing direction by applying a first latching clock signal to first shift register stage 204 and a second suppression clock signal to second shift register stage 206, followed by a third latching clock signal to third shift register stage 208 and a first suppression clock signal to first shift register stage 204.

In implementations where each of first, second, and third sets of shift register stages includes a plurality of shift register stages, such as in superconducting circuits 200b and 300a of FIGS. 2C and 3A, qubit state information of the second plurality of qubits is shifted through alternating ones of shift register stages of each plurality of shift register stages.

Information can be shifted in a first direction along shift register stages of the third, the first, and the second sets of shift register stages until reaching a terminating shift register stage by alternating ones of third, first, and second latching clock signals and suppression clock signals. Alternatively, for example to read out from a different readout interface, information can be shifted in a second direction along shift register stages of the first, the third, and the second sets of shift register stages until reaching a terminating shift register stage by alternating ones of first, third, and second clock latching clock signals and suppression clock signals.

In implementations where more than one qubit of the second plurality of qubits is coupled to a respective shift register stage of the second set of shift register stages, qubit state information of all qubits of the second plurality of qubits are concurrently or even synchronously propagated along the shift register.

In some implementations, reading out the qubit state information of the first set of qubits further includes propagating qubit state information of qubits of the first set of qubits along at least one communication shift register, and transmitting the qubit state information to at least one readout interface. This can be performed as described above with respect to act 806.

Subsequent to act 810, method 800 is terminated until, for instance, it is invoked again.

As described above with respect to first and second qubits 202a and 202b in superconducting circuit 200a, a Josephson junction of each qubit in a quantum processor can be coupled to an analog line, such as analog line 216. In implementations used to perform accelerated readout schemes, a Josephson junction of each qubit in a quantum processor can be coupled to one of six analog lines. The coupling can be arranged such that no two coupled qubits in the quantum processor are coupled to a same analog line.

FIGS. 9A and 9B respectively illustrate two superconducting circuit configurations to read out a portion of an example readout system. FIGS. 9A and 9B show respective superconducting circuit configurations 900a and 900b that include superconducting circuits that are substantially the same as superconducting circuit 300a. However, the shift registers of superconducting circuits of superconducting circuit configurations 900a and 900b include shift register stages that are communicatively coupled to clock lines carrying CLOCK 3′ signals and CLOCK 4′ signals in addition to shift register stages that are communicatively coupled to clock lines carrying CLOCK 3 signals, CLOCK 4 signals, and CLOCK 5 signals. Shift register stages coupled to these two new additional clock lines are loaded and latched or suppressed based on clock signals carried via these clock lines.

For superconducting circuit configurations 900a and 900b, three analog lines can be coupled to Josephson junctions of qubits oriented in a first direction and substantially parallel to one another (i.e., coupled to shift registers of a first plurality of shift registers, such as first plurality of shift registers 302 of FIG. 3A), and the remaining three analog lines can be coupled to Josephson junctions of qubits that are oriented in a second direction that is substantially perpendicular to the first direction (i.e., coupled to shift registers of a second plurality of shift registers as described herein with respect to FIG. 3A). Analog lines can be coupled to Josephson junctions of qubits such that all qubits read out by a same shift register are coupled to a same analog line.

Both superconducting circuit configurations 900a and 900b are annotated to include a dashed line indicating a center of a topology of a quantum processor. In FIGS. 9A and 9B, this dashed line is indicative of an axis along a midline of the processor. However, the dashed line will hereinafter be referred to as a defined shift register location 902. Both superconducting circuit configurations 900a and 900b are also annotated to include arrows illustrating a direction of qubit state information transmission along its readout shift registers.

In FIG. 9A, clock lines carrying CLOCK 3′ and CLOCK 4′ signals are operated in the same manner as clock lines carrying CLOCK 3 and CLOCK 4 signals, respectively (i.e., CLOCK 3 and CLOCK 3′ signals are synchronized, and CLOCK 4 and CLOCK 4′ signals are synchronized).

In operation, qubit state information can be transmitted from a qubit to a shift register of the plurality of shift registers, as described above with respect to method 800. Qubits in communication with shift register stages coupled to clock lines carrying CLOCK 3 and CLOCK 3′ signals, are all loaded and latched during one of the first or second pass. Qubits in communication with second shift register stages coupled to clock lines carrying CLOCK 4 and CLOCK 4′ signals are loaded and latched during the other one of the first or second pass.

In such an arrangement, qubit state information is shifted along alternating shift registers of the first plurality of shift register in opposing directions. For instance, as illustrated in FIG. 9A: qubit state information of qubits read out by any shift register stage of a first shift register 904a is propagated along a first direction; qubit state information of qubits read out by any shift register stage of a second shift register 904b is propagated along a second direction that opposes the first direction; qubit state information of qubits read out by any shift register stage of a third shift register 904c is propagated along the first direction; and, qubit state information of qubits read out by any shift register stage of a first shift register 904d is propagated along the second direction.

In FIG. 9B, clock lines carrying CLOCK 3′ and CLOCK 4 signals are operated in the same manner and clock lines carrying CLOCK 3 and CLOCK 4′ signals are operated in the same manner (i.e., CLOCK 3′ and CLOCK 4 signals are synchronized, and CLOCK 3 and CLOCK 4′ signals are synchronized).

Via superconducting circuit configuration 900b, qubit state information can be transmitted from a qubit to a shift register of the plurality of shift registers as described above with respect to method 800. Qubits in communication with shift register stages that are coupled to clock lines carrying CLOCK 3′ and CLOCK 4 signals are all loaded and latched during one of the first or second pass. Qubits in communication with shift register stages coupled to clock lines carrying CLOCK 3 and CLOCK 4′ signals are loaded and latched during the other one of the first or second pass.

The described operation of superconducting circuit configuration 900b provides bifurcated readout of qubit state information. Here, a location of a shift register stage coupled to a corresponding qubit from which qubit state information originates determines a direction of shifting the qubit state information for read out. A given shift register stage positioned on a first side of defined shift register location 902 propagates qubit state information in a first direction for readout, regardless of which shift register the given shift register is part of. Similarly, a given shift register stage positioned on a second side of defined shift register location 902 propagates qubit state information in a second direction for readout, regardless of which shift register the given shift register is part of. In other words, each bit of qubit state information is shifted laterally from defined shift register location 902 to minimize a number of shift register stages through which it is transmitted. As a result, superconducting circuit configuration 900b can provide accelerated operation of reading out qubit state information relative to superconducting circuit configuration 900a.

Although accelerated readout of qubit state information has been described above where defined shift register location 902 is an axis defining a midline of the quantum processor, defined shift register location 902 can be any point within the quantum processor and/or shift register that defines where bifurcation of qubit state information propagation occurs. In some implementations, this defined shift register location can be the same across all shift registers of the first plurality of shift registers. In some implementations, a defined shift register location can be uniquely defined for each shift register of the first plurality of shift registers.

It is to be understood that other readout schemes can be realized for superconducting circuit 300a and readout system 300b. Qubits of superconducting circuit 300a can be coupled to different analog lines based on the shift register used for read out. For instance, with reference to FIGS. 9A and 9B: qubits coupled to first shift register 904a may be coupled to a first analog line; qubits coupled to second shift register 904b may be coupled to a second analog line; qubits coupled to third shift register 904c may be coupled to a third analog line; and, qubits coupled to fourth shift register 904d may be coupled to the first analog line. A similar pattern may be repeated across a larger readout system.

The shift register stages labeled “3′” and “4′” can instead be coupled to added clock lines based on the analog line to which a corresponding qubit is coupled. For instance: shift register stages of first shift register 904a and fourth shift register 904d labeled “3′” can be coupled to a clock line carrying a “CLOCK 3A” signal; shift register stages of second shift register 904b labeled “3′” can be coupled to a clock line carrying a “CLOCK 3B” signal; and shift register stages of second shift register 904b labeled “3′” can be coupled to a clock line carrying a “CLOCK 3B” signal.

Based on the above-described arrangement, readout schemes of 9A and 9B can be performed for specific sub-set of qubits within the quantum processor.

In some implementations, the readout scheme as described with respect to FIG. 9A can be performed to read out all qubits coupled to a same analog line, and all of such qubits coupled to a same shift register are read out by a same readout interface, i.e., by propagating qubit state information in a same direction. For example, qubit state information of first shift register 904a and fourth shift register 904d (i.e., qubits coupled to the first analog line) can be read out as shown in FIG. 9A.

In some implementations, the readout scheme as described with respect to FIG. 9B can be performed to read out all qubits coupled to a same analog line in a bifurcated manner, i.e., by propagating qubit state information to a closest readout interface.

Accelerated readout schemes can also be realized using readout systems based on the arrangement of superconducting circuit 400 of FIG. 4, including readout system 500 of FIG. 5.

FIG. 10A and FIGS. 10B and 10C illustrate two implementations of reading out a portion of an example readout system, in accordance with the present systems and devices. Superconducting circuit configurations 1000a, 1000b, and 1000c of FIGS. 10A, 10B, and 10C respectively all include an example portion of a readout system that is similar to a portion of readout system 500. It is to be understood that although only shift registers of a first plurality of readout shift registers, such as 502a of readout system 500, are shown, shift registers of a second plurality of readout shift registers that are communicatively coupled to the first plurality of readout shift registers can also be included in superconducting circuit configurations 1000a, 1000b, and 1000c.

The portion of the readout system shown by superconducting circuit configurations 1000a, 1000b, and 1000c also differs from readout system 500 (FIG. 5) at least in that they show an expanded representation of: readout interface chains 506 to illustrate communication shift registers and readout interfaces, such as communication shift register 412 and readout interface 414 of FIG. 4; and, readout chains 508 to illustrate communicatively coupled sets of latches and corresponding qubits.

In superconducting circuit configurations 1000a, 1000b, and 1000c, qubits coupled to the readout system are labeled as “A”, “B”, and “C”, corresponding to labels of three analog lines (not called out in FIGS. 10A, 10B, 10C.) that are respectively communicatively coupled to Josephson junctions of each qubit. While the analog lines are not shown in FIGS. 10A, 10B, and 10C to reduce clutter, qubits labeled ‘A’ are coupled to analog line ‘A’, qubits labeled ‘B’ are coupled to analog line ‘B’, and qubits labeled ‘C’ are coupled to analog line ‘C’. As can be seen in FIGS. 10A-10C, all qubits that are read out by a same readout shift register are coupled to a same analog line.

In superconducting circuit configurations 1000a, 1000b, and 1000c, each shift register stage that is communicatively coupled to a unique qubit via a unique set of latches has one of the following labels: “3”, “4”, “3A”, “4A”, “3B”, “4B”, “3C”, and “4C”. Each of the previously noted labels corresponds to a clock line to which the shift register stage is communicatively coupled via, for example, an inductive interface. For instance, a shift register stage labeled “3B” is operated based on a CLOCK 3B signal transmitted across a dedicated clock line.

Qubits having Josephson junctions that are communicatively coupled to analog line “A” are read out by shift register stages operated based on one of the following signals: CLOCK 3, CLOCK 4, CLOCK 3A, and CLOCK 4A. Qubits having Josephson junctions that are communicatively coupled to analog line “B” are read out by shift register stages operated based on one of the following signals: CLOCK 3, CLOCK 4, CLOCK 3B, and CLOCK 4B. Qubits having Josephson junctions that are communicatively coupled to analog line “C” are read out by shift register stages operated based on one of the following signals: CLOCK 3, CLOCK 4, CLOCK 3C, and CLOCK 4C.

Although not shown, three different analog lines can be communicatively coupled to Josephson junctions of qubits that are read out by shift registers of the second plurality of readout shift registers. In some implementations, reading out qubits coupled to the three additional clock lines can be based on six additional clock signals carried by dedicated clock lines. In other implementations, clock lines transmitting signals CLOCK 3A, CLOCK 4A, CLOCK 3B, CLOCK 4B, CLOCK 3C, and CLOCK 4C can also be coupled to shift registers in the second plurality of readout shift registers in the manner described above.

Superconducting circuit configuration 1000a of FIG. 10A illustrates full readout of the portion of the readout system used in the quantum processor. Here, qubit state information corresponding to each qubit in the quantum processor is propagated along one or more readout shift registers and through a communication shift register to be read out at one readout interface. Qubit state information is shifted in a serpentine, circuitous path along the readout shift registers of the portion of the readout system. The readout provided by superconducting circuit configuration 1000a can provide significant redundancy in the readout system, such that readout might not be disrupted by missing or faulty shift register stages.

In superconducting circuit configuration 1000a, clock lines carrying CLOCK 3, CLOCK 3A, CLOCK 3B and CLOCK 3C signals can all be operated in a same manner as a first group of clock signals, such that transitions between their latching clock signals and suppression clock signals can be synchronous across correspondingly coupled readout shift register stages. As well, clock lines carrying CLOCK 4, CLOCK 4A, CLOCK 4B, and CLOCK 4C signals can all be operated in a same manner as a second group of clock signals, such that transitions between their latching clock signals and suppression clock signals can be synchronous across correspondingly coupled readout shift register stages.

Superconducting circuit configuration 1000a can propagate qubit state information along readout shift registers of the portion of the readout system in a “descending” direction, as indicated by the annotated arrows included in FIG. 10A. Cycling qubit information in the descending direction can result from clock signal application in the following sequence: applying a CLOCK 5 latching signal to all correspondingly coupled readout shift register stages and applying a suppression signal of the first group of clock signals to all correspondingly coupled readout shift register stages; applying a latching clock signal of the second group of clock signals to all correspondingly coupled readout shift register stages and applying a CLOCK 5 suppression signal to all correspondingly coupled readout shift register stages; and, applying a latching clock signal of the first group of clock signals to all correspondingly coupled readout shift register stages and applying a suppression signal of the second group of clock signals to all correspondingly coupled readout shift register stages.

In operation, qubit state information can be transmitted from a qubit to a shift register of the plurality of readout shift registers as described with respect to method 800 using two passes. Qubits in communication with readout shift register stages coupled to clock lines carrying clock signals of the first group of clock signals are all loaded and latched during one of the first or second pass. Qubits in communication with second shift register stages coupled to clock lines carrying clock signals of the second group of clock signals are all are loaded and latched during the other one of the first or second pass.

In an example operation, performing a first pass of reading out the portion of the readout system provided by superconducting circuit configuration 1000a can include reading out qubit state information from qubits corresponding to shift register stages that are coupled to clock lines carrying clock signals of the first group of clock signals (i.e., all shift register stages labeled “3”, “3A”, “3B”, and “3C” in FIG. 10A, herein also collectively known as first shift register stages). The qubit state information in each shift register-proximate latch is shifted to its respective first shift register stage based on a respective latching clock signal of the first group of clock signals. Qubit state information is shifted along readout shift registers via successive CLOCK 5 latching clock signals and suppression clock signals, latching clock signals and suppression clock signals of the second group of clock signals, and latching clock signals and suppression clock signals of the first group of clock signals. Bits of qubit state information are cycled through shift register stages of at least one readout shift register until, for instance, each bit of qubit state information has been transmitted to at least one operational readout interface via at least one respective communication shift register.

In some implementations, bits of qubit state information can optionally be cycled through all shift registers of the plurality of shift registers until, for instance, each bit of qubit state information has been shifted through each readout shift register stage in the readout system. Each of these bits of qubit state information can also optionally be shifted along one, some, or all of the communication shift registers to be readout by a respective one, some, or all of the readout interfaces.

Following the same example operation, performing a second pass of reading out the portion of the readout system provided by superconducting circuit configuration 1000a can include reading out qubit state information from qubits corresponding to shift register stages that are coupled to clock lines carrying clock signals of the second group of clock signals (i.e., all shift register stages labeled “4”, “4A”, “4B”, and “4C” in FIG. 10A, herein also collectively known as second shift register stages). The qubit state information in each intermediate latch is shifted to its respective shift register-proximate latch via a CLOCK 2 latching signal and a CLOCK 1 suppression signal, and then to its respective second shift register stage via latching clock signals of the second group of clock signals and a CLOCK 2 suppression signal. Qubit state information is shifted along readout shift registers in a descending direction via successive latching clock signals and suppression clock signals of the first group of clock signals, CLOCK 5 latching clock signals and suppression clock signals, and latching clock signals and suppression clock signals of the second group of clock signals. Bits of qubit state information are cycled through shift register stages of at least one readout shift register until, for instance, each bit of qubit state information has been transmitted to at least one operational readout interface via at least one respective communication shift register.

In some implementations, bits of qubit state information can be optionally cycled through all shift registers of the plurality of shift registers until, for instance, each bit of qubit state information has been shifted through each readout shift register stage in the readout system. Each of these bits of qubit state information can also optionally be shifted across one, some, or all of the communication shift registers to be readout by a respective one, some, or all of the readout interfaces.

FIG. 10A and the example above describes reading out qubit state information from qubits coupled to first shift registers in a first pass and from qubits coupled to second shift registers in a second pass. However, this is merely an example. In an alternative implementation, a first pass can include reading out qubit state information from qubits coupled to second shift registers in a first pass and from qubits coupled to first shift registers in a second pass.

Although Figure TOA and the example above describes shifting qubit state information across the readout shift registers in a descending direction, qubit state information can also or alternatively be cycled through readout shift registers in an opposing ascending direction. Cycling qubit information in the descending direction can result from clock signal application in the following sequence: applying a latching clock signals and suppression clock signals of the first group of clock signals to all first shift register stages; applying latching clock signals and suppression clock signals of the second group of clock signals to all second shift register stages; and, applying a CLOCK 5 latching signal and suppression signal to all correspondingly coupled readout shift register stages.

In some implementations, both a first pass and a second pass of readout can be performed in an ascending direction. In some implementations, one of the first pass or the second pass can be performed in a descending direction and the other one of the first pass or the second pass can be performed in an ascending direction.

FIGS. 10B and 10C show superconducting circuit configurations 1000b and 1000c that illustrate first and second passes of an example accelerated readout scheme. The shown accelerated readout scheme read out qubit state information associated with qubits labeled “B” (which correspond to qubits having Josephson junctions coupled to not shown analog line “B” as described above) in a bifurcated manner. FIGS. 10B and 10C are annotated to include a dashed line indicative of a center of a topology of a quantum processor, which hereinafter may be referred to as a defined shift register location 1006. Arrows located on shift registers in FIGS. 10B and 10C indicate where data transmission occurs among the plurality of readout shift registers and in which direction data is transported or shifted. Arrows along readout chains indicate the readout chains from which the qubit state information originates during a particular pass of the readout scheme.

In FIGS. 10B and 10C, qubit state information is read out from the two illustrated readout shift registers 1002a, 1002b across which each coupled qubit is a qubit labeled “B”. Qubits coupled to shift register stages of first and second shift registers 1002a and 0102b on a first side of defined shift register location 1006 are shifted in a first direction to be read out by first and second readout interfaces 1004a and 1004b. Qubits coupled to shift register stages of first and second shift registers 1002a and 1002b on a second side of defined shift register location 1006 are shifted in a second direction to be read out by third and fourth readout interfaces 1004c and 1004d.

Superconducting circuit configurations 1000b illustrates the first pass of the example accelerated readout scheme. To perform the first pass, qubit state information can be shifted substantially as described with respect to method 800. Here, CLOCK 3B and CLOCK 4B signals can be synchronously transmitted across their respective dedicated clock lines. The CLOCK 3B and CLOCK 4B latching signals are applied to a Josephson junction of each respectively coupled shift register stage across a respective clock line interface. Resultantly, the shift register stages labeled “3B” and “4B” in superconducting circuit configuration 1000b are latched with the qubit state information of qubits as shown in FIG. 10B.

The qubit state information is then propagated along first and second shift registers 1002a, 1002b to first, second, third, and fourth readout interfaces 1004a, 1004b, 1004c, 1004d as indicated by the annotated arrows shown in FIG. 10B. This can be achieved by sequential and alternative latching of shift register stages via transmission of latching signals and suppression signals of the following clock signals: CLOCK 5 signals; CLOCK 3 and CLOCK 4 signals; and, CLOCK 3B and CLOCK 4B signals.

Once each bit of the qubit state information reaches the shift register stage labeled “5T”, the qubit state information can be shifted to a corresponding readout interface via propagation along a respective communication shift register based on sequential and alternative latching and suppression of shift register stages based on CLOCK 6 signals, CLOCK 7 signals, and, CLOCK 8 signals. The shift operations of shift register stages of communication shift registers are performed concurrently or even simultaneously with the cycling of qubit state information through the readout shift registers. The qubit state information can be read out by a readout interface (i.e., one of 1004a, 1004b, 1004c, and 1004d), for example, by coupling a state information signal to a superconducting resonator via an inductive interface.

Superconducting circuit configuration 1000c illustrates the second pass of the example accelerated readout scheme. To perform the second pass, CLOCK 3 and CLOCK 4 latching signals can be synchronously transmitted across their respective dedicated clock lines such that they are coupled to a Josephson junction of respective shift register stages labeled “3” and “4” of first and second readout shift register 1002a, 1002b. This thereby latches the shift register stages labeled “3” and “4” with the qubit state information of qubits as shown in FIG. 10C.

The qubit state information is then propagated along first and second shift registers 1002a, 1002b to first, second, third, and fourth readout interfaces 1004a, 1004b, 1004c, 1004d as indicated by the annotated arrows shown in FIG. 10C. This can be achieved by sequential and alternative latching of shift register stages of first and second shift registers 1002a, 1002b via transmission of the following latching and suppression clock signals: CLOCK 3B and CLOCK 4B signals; CLOCK 5 signals; and, CLOCK 3 and CLOCK 4 signals. The subsequent propagation of qubit state information through communicatively coupled communication shift registers to first, second, third, and fourth readout interfaces 1004a, 1004b, 1004c, 1004d is performed as described with respect to the first pass.

When using example accelerated readout scheme, the following clock signals are suppressed: CLOCK 3A signals, CLOCK 4A signals, CLOCK 3C signals, and CLOCK 4C signals. In doing so, shift register stages labeled “3A”, “4A”, “3C”, and “4C” do not latch qubit state data at any point during the operation. As a result, when CLOCK 3 signals and CLOCK 4 signals cause shift register stages labeled “3” and “4” to latch qubit state information of qubits labeled “A” and “C”, this qubit state information is not propagated through the readout system thereafter.

Although the example accelerated readout scheme described above pertains to read out of qubits labeled “B” (that, though not shown, are coupled to an analog line “B”), one would understand that a similar scheme can be applied to read out of qubits labeled “A” or labeled “C” (that, though not shown, are respectively coupled to an analog line “A” or an analog line “C”).

For a readout system including N readout shift register stages in each shift register, the greatest distance from an axis defining a midline of the quantum processor, such as defined shift register location 1006 of FIGS. 10B and 10C, to the edge of a given readout shift register is approximately N/2. The above-described accelerated readout scheme advantageously reduces an amount of time required to read out or calibrate qubits coupled to a particular analog line by half compared to the scheme described with respect to superconducting circuit configuration 1000a, as qubit state information is transmitted across a maximum of N/2 shift register stages.

Although accelerated readout of qubit state information has been described above with respect to defined shift register location 1006 being an axis defining a midline of the quantum processor, a location defining where bifurcated qubit state information propagation occurs can be located at anywhere across the quantum processor and/or shift register. In some implementations, this defined shift register location can be the same across all shift registers having a same orientation. In some implementations, a defined shift register location can be uniquely defined for each shift register.

In implementations that are not illustrated, clock signals transmitted via the above-described clock lines can be applied to correspondingly coupled shift register stages to provide different operations.

For instance, the readout system can perform unidirectional reads, in which latching and suppression clock signals can be selectively transmitted to readout all qubit state information of qubits coupled to a same analog line by transmitting qubit state information along communicatively coupled shift registers in a same direction for readout by one readout interface per shift register.

As another example, a first sequence of latching and suppression clock signals can be selectively transmitted to perform a bifurcated readout of all qubit state information corresponding to qubits coupled to non-nearest-neighbor shift registers using two passes. As well, a second sequence of latching and suppression clock signals can be selectively transmitted to perform a bifurcated readout of all qubit state information corresponding to qubits coupled to the remaining, unread shift registers using two passes. This readout scheme can be used to provide accelerated readout of all qubits in the quantum processor using four passes.

### Post-Amble

The above described method(s), process(es), or technique(s) could be implemented by a series of processor readable instructions stored on one or more non-transitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for example purposes only and may change in alternative examples. Some of the example acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the example methods for quantum computation generally described above.

The various implementations described above can be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to: U.S. Pat. Nos. 7,135,701; 7,418,283; 7,533,068; 7,843,209; 8,008,942; 8,195,596; 8,190,548; 8,421,053; 8,772,759; 9,170,278; 9,178,154; 9,710,758; 10,938,346; and 11,100,416; US Patent Application Publication No. 2019/0220771; U.S. Provisional Patent Applications Nos. 63/227,395 and 62/851,377; and, International Patent Application PCT/US22/38498.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A superconducting circuit comprising:
a plurality of qubits including a first set of qubits and a second set of qubits;
at least one readout shift register, each readout shift register of the at least one readout shift register including: a first set of shift register stages, a second set of shift register stages, and a third set of shift register stages; and,
a respective set of latches corresponding to each qubit of the plurality of qubits, wherein the latches of each set of latches are communicatively coupled to one another in series, and, for each readout shift register:
at least one shift register stage of a respective first set of shift register stages is communicatively coupled to a respective qubit of the first set of qubits via a respective set of latches,
at least one shift register stage of a respective second set of shift register stages is communicatively coupled to a respective qubit of the second set of qubits via a respective set of latches, and
each shift register stage of a respective third set of shift register stages is communicatively coupled to at least one of: a shift register stage of the first set of shift register stages and a shift register stage of the second set of shift register stages, and to exclusively perform shift operations.

2. The superconducting circuit of claim 1, wherein:
each shift register stage of each first set of shift register stages is communicatively coupled to one shift register stage of a respective second set of shift register stages and one shift register of a respective third set of shift register stages; and
each shift register stage of each second set of shift register stages is communicatively coupled to one shift register stage of a respective first set of shift register stages and one shift register of a respective second set of shift register stages.

3. The superconducting circuit of claim 1, further comprising, for each readout shift register:
all shift register stages of the first set of shift register stages are communicatively coupled to a first clock line, the first clock line operable to carry first clock signals to latch the first set of shift register stages;
all shift register stages of the second set of shift register stages are communicatively coupled to a second clock line, the second clock line operable to carry second clock signals to latch the second set of shift register stages; and,
all shift register stages of the third set of shift register stages are communicatively coupled to a third clock line, the third clock line operable to carry third clock signals that to latch the third set of shift register stages.

4. The superconducting circuit of claim 3, wherein each set of latches comprises at least:
a first latch communicatively coupled to a respective qubit of the plurality of qubits;
one or more intermediate latches, wherein at least one latch of the one or more intermediate latches is communicatively coupled to the first latch; and,
a final latch communicatively coupled to a respective shift register stage and at least one latch of the one or more intermediate latches,
wherein all first latches are communicatively coupled to a first latch clock line operable to carry first latch clock signals to latch the first latches, all intermediate latches of the one or more intermediate latches are communicatively coupled to respective intermediate latch clock lines operable to carry intermediate latch clock signals to latch the at least one intermediate latches, and all final latches are communicatively coupled to a final latch clock line operable to carry final latch clock signals to latch the final latches.

5. The superconducting circuit of claim 4, wherein each shift register stage of the first, the second, and the third sets of shift register stages of each readout shift register comprises a Josephson junction operable to communicably receive a respective one of the first clock signals, the second clock signals, and the third clock signals, and
each latch of the first, the one or more intermediate, and the final latches of each set of latches comprises a Josephson junction operable to communicably receive a respective one of the first latch clock signals, the at least one intermediate latch clock signals, and the final latch clock signals.

6. The superconducting circuit of claim 1, wherein shift register stages of the first, the second, and the third sets of shift register stages of each readout shift register, and the sets of latches comprise at least one material that exhibits superconducting behavior at and below a respective material critical temperature.

7. The superconducting circuit of claim 1, wherein each shift register stage of the first, the second, and the third sets of shift register stages of each shift register, and each latch of each of the sets of latches comprises a respective quantum flux parametron (QFP).

8. The superconducting circuit of claim 1, wherein for each readout shift register, at least one terminating shift register stage is communicatively coupled to a respective communication shift register, and each communication shift register is communicatively coupled to a respective readout interface.

9. The superconducting circuit of claim 8, wherein each communication shift register comprises alternating shift registers stages of a first, a second, and a third set of communication shift register stages that are respectively communicatively coupled to one of a first, a second, and a third communication clock line, each one of the first, the second, and the third communication clock lines to carry a respective clock signal to latch shift registers stages of a respective one of the first, the second, and the third set of communication shift register stages, and wherein each shift register stage of the communication shift register comprises a QFP.

10. The superconducting circuit of claim 8, wherein each readout interface comprises a superconducting microwave resonator comprising a first and a second superconducting quantum interference device (SQUID) arranged in series along a superconducting loop, and the terminating shift register stage of a respective communication shift register is inductively coupled to the second SQUID of the superconducting microwave resonator to transmit the qubit state information corresponding to qubits of the plurality of qubits to the readout interface.

11. The superconducting circuit of claim 10, wherein the first and the second SQUIDs of the superconducting microwave resonator are operable as tunable non-linear inductors to independently tune a resonant frequency and a sensitivity of the superconducting microwave resonator.

12. The superconducting circuit of claim 1, wherein:
the superconducting circuit comprises a first plurality of readout shift registers arranged in parallel to one another along a major portion of a respective length of each readout shift register of the first plurality of readout shift registers; and
the plurality of qubits comprises a first plurality of qubits, wherein the first plurality of qubits includes a first subset of the first set of qubits and a first subset of the second set of qubits that cross the first plurality of readout shift registers at a non-zero angle,
wherein a pair of readout shift registers of the first plurality of readout shift registers crosses each qubit of the first plurality of qubits, and each qubit of the first plurality of qubits is coupled to one readout shift register of a respective pair of readout shift register via communicative coupling of one superconducting loop of the respective qubit to a respective set of latches.

13. The superconducting circuit of claim 12, further comprising a second plurality of readout shift registers arranged in parallel to one another along a major portion of a respective length of each readout shift register of the second plurality of readout shift registers and that cross the first plurality of readout shift registers at a non-zero angle, and the plurality of qubits comprising a second plurality of qubits that includes second subset of the first set of qubits and a second subset of the second set of qubits that cross the second plurality of readout shift registers at a non-zero angle,
wherein a pair of readout shift registers of the second plurality of readout shift registers crosses each qubit of the second plurality of qubits, and each qubit of the second plurality of qubits is coupled to one readout shift register of a respective pair of readout shift registers via communicative coupling of one superconducting loop of the respective qubit to a respective set of latches.

14. The superconducting circuit of claim 12, wherein each readout shift register of the first and the second pluralities of readout shift registers comprises two terminating shift register stages that are communicatively coupled to a respective communication shift register, and wherein each communication shift register is communicatively coupled to a respective readout interface.

15. The superconducting circuit of claim 12, wherein:
the first set of shift register stages comprises at least a first subset of first shift register stages and a second subset of first shift register stages,
wherein each shift register stage of the first subset of first shift register stages is communicatively coupled to a first clock line operable to carry first clock signals to latch the first subset of first shift register stages, and
wherein each shift register stage of the second subset of first shift register stages is communicatively coupled to a second clock line operable to carry second clock signals to latch the second subset of first shift register stages;
the second set of shift register stages comprises at least a first subset of second shift register stages and a second subset of second shift register stages,
wherein each shift register stage of the first subset of second shift register stages is communicatively coupled to a third clock line operable to carry third clock signals to latch the first subset of second shift register stages, and
wherein each shift register stage of the second subset of second shift register stages is communicatively coupled to a fourth clock line operable to carry fourth clock signals to latch the second subset of second shift register stages; and,
each shift register stage of the third set of shift register stages is communicatively coupled to a fifth clock lines operable to carry fifth clock signals to latch shift register stages of the third set of shift register stages.

16. The superconducting circuit of claim 1, wherein the superconducting circuit comprises at least one pair of readout shift registers and at least one interstitial bus, wherein readout shift registers of each pair of readout shift registers are communicatively coupled to one another via a respective interstitial bus of the at least one interstitial bus, and each interstitial bus is communicatively coupled to a respective readout interface via a respective communication shift register.

17. The superconducting circuit of claim 16, wherein each interstitial bus of the at least one interstitial bus comprises one shift register stage belonging to each of the first, the second, and the third sets of shift register stages, each communication shift register comprises a plurality of communication shift register stages, and the one shift register stage of the third set of shift register stages of the interstitial bus is communicatively coupled to a first communication shift register stage of the communication shift register.

18. The superconducting circuit of claim 16, further comprising:
a first plurality of readout shift registers that are parallel to one another along a majority of a respective length of each readout shift register of the first plurality of readout shift registers and oriented in a first direction, wherein the at least one pair of readout shift registers that are communicatively coupled to one another via a respective interstitial bus comprises each nearest-neighbor pair of readout shift registers of the first plurality of readout shift registers;
a second plurality of shift readout registers that are parallel to one another along a majority of a respective length of each readout shift register of the second plurality of readout shift registers and oriented in a second direction that is different to the first direction, wherein the at least one pair of readout shift registers that are communicatively coupled to one another via a respective interstitial bus further comprises each nearest-neighbor pair of readout shift registers of the second plurality of readout shift registers; and,
at least two connection buses, wherein each connection bus communicatively couples one shift register of the first plurality of readout shift registers to one shift register of the second plurality of readout shift registers.

19. The superconducting circuit of claim 17, wherein:
qubits of the plurality of qubits that are communicatively coupled to shift registers of the first plurality of readout shift registers comprise: a first, a second, and a third plurality of qubits, each one of the first, the second, and the third pluralities of qubits including a respective one of a first, a second, and a third subset of the first set of qubits and a respective one of a first, a second, and a third subset of the second set of qubits,
wherein each qubit of the first, the second, and the third pluralities of qubits includes a Josephson junction that is communicatively coupled to a respective one of a first, a second, and a third analog interface, and
all qubits that are communicatively coupled to a same one of the shift registers of the first plurality of readout shift registers belong to a same one of the first plurality of qubits, the second plurality of qubits, and the third plurality of qubits; and,
qubits of the plurality of qubits that are communicatively coupled to shift registers of the second plurality of readout shift registers comprise: a fourth, a fifth, and a sixth plurality of qubits, each one of the fourth, the fifth, and the sixth pluralities of qubits including a respective one of a fourth, a fifth, and a sixth subset of the first set of qubits and a respective one of a fourth, a fifth, and a sixth subset of the second set of qubits,
wherein each qubit of the fourth, the fifth, and the sixth pluralities of qubits includes a Josephson junction that is communicatively coupled to a respective one of a fourth, a fifth, and a sixth analog interface, and
all qubits that are communicatively coupled to a same one of the shift registers of the second plurality of readout shift registers belong to a same one of the fourth plurality of qubits, the fifth plurality of qubits, and the sixth plurality of qubits.

20. The superconducting circuit of claim 19, wherein for the first plurality of readout shift registers:
the first set of shift register stages comprises: a first, a second, a third, and a fourth subset of first shift register stages,
each shift register stage of the first subset of first shift register stages is communicatively coupled to: one qubit of the first plurality of qubits, and a clock line carrying a first subset-first clock signal,
each shift register stage of the second subset of first shift register stages is communicatively coupled to: one qubit of the second plurality of qubits, and a clock line carrying a second subset-first clock signal,
each shift register stage of the third subset of first shift register stages is communicatively coupled to: one qubit of the third plurality of qubits, and a clock line carrying a third subset-first clock signal, and
each shift register stage of the fourth subset of first shift register stages is communicatively coupled to: one qubit of any one of the first, the second, and the third pluralities of qubits, and a clock line carrying a fourth subset-first clock signal;
the second set of shift register stages comprises: a first, a second, a third, and a fourth subset of second shift register stages,
each shift register stage of the second subset of first shift register stages is communicatively coupled to: one qubit of the first plurality of qubits, and a clock line carrying a first subset-second clock signal,
each shift register stage of the second subset of second shift register stages is communicatively coupled to: one qubit of the second plurality of qubits, and a clock line carrying a second subset-second clock signal,
each shift register stage of the third subset of second shift register stages is communicatively coupled to: one qubit of the third plurality of qubits, and a clock line carrying a third subset-second clock signal, and
each shift register stage of the fourth subset of second shift register stages is communicatively coupled to: one qubit of any one of the first, the second, and the third pluralities of qubits, and a clock line carrying a fourth subset-second clock signal; and,
each shift register stage of the third set of shift register stages is communicatively coupled to a clock line carrying a third clock signal.

21. The superconducting circuit of claim 20, wherein for the second plurality of readout shift registers:
the first set of shift register stages comprises: a fifth, a sixth, a seventh, and an eighth subset of first shift register stages,
each shift register stage of the fifth subset of first shift register stages is communicatively coupled to: one qubit of the fourth plurality of qubits, and the clock line carrying the first subset-first clock signal,
each shift register stage of the sixth subset of first shift register stages is communicatively coupled to: one qubit of the fifth plurality of qubits, and the clock line carrying the second subset-first clock signal,
each shift register stage of the seventh subset of first shift register stages is communicatively coupled to: one qubit of the sixth plurality of qubits, and the clock line carrying the third subset-first clock signal, and
each shift register stage of the eighth subset of first shift register stages is communicatively coupled to: one qubit of any one of the fourth, the fifth, and the sixth pluralities of qubits, and the clock line carrying the fourth subset-first clock signal;
the second set of shift register stages comprises: a fifth, a sixth, a seventh, and an eighth subset of second shift register stages,
each shift register stage of the fifth subset of second shift register stages is communicatively coupled to: one qubit of the fourth plurality of qubits, and the clock line carrying the first subset-first clock signal,
each shift register stage of the sixth subset of second shift register stages is communicatively coupled to: one qubit of the fifth plurality of qubits, and the clock line carrying the second subset-first clock signal,
each shift register stage of the seventh subset of first shift register stages is communicatively coupled to: one qubit of the sixth plurality of qubits, and the clock line carrying the third subset-first clock signal, and
each shift register stage of the eighth subset of first shift register stages is communicatively coupled to: one qubit of any one of the fourth, the fifth, and the sixth pluralities of qubits, and the clock line carrying the fourth subset-first clock signal; and,
each shift register stage of the third set of shift register stages is communicatively coupled to the clock line carrying the third clock signal.

22. A method of transmitting data from a plurality of qubits including a first set of qubits and a second set of qubits, wherein sets of latches communicatively couple the plurality of qubits to at least one shift register that comprises a first set of shift register stages, a second set of shift register stages, and a third set of shift register stages, wherein each qubit of the first set of qubits is communicatively coupled to a respective shift register stage of the set of first shift register stages via a set of latches, and each qubit of the second set of qubits is communicatively coupled to a respective shift register stage of the set of second shift register stages via a set of latches, the method comprising:
shifting qubit state information of each qubit of the plurality of qubits to a respective holding latch of a corresponding set of latches;
obtaining, by each shift register stage of the first set of shift register stages, qubit state information of each qubit of the first set of qubits from a respective holding latch via a respective final latch;
propagating the qubit state information of the first set of qubits along at least one shift register stage of the second set of shift register stages and at least one shift register stage of the third set of shift register stages to read out the qubit state information of the first set of qubits;
obtaining, by each shift register stage of the second set of shift register stages, qubit state information of each qubit of the second set of qubits from a respective holding latch via a respective final latch; and,
propagating the qubit state information of the second set of qubits along at least one shift register stage of the third set of shift register stages to read out the qubit state information of the second set of qubits.

23. The method of claim 22, wherein the shifting qubit state information of each qubit of a plurality of qubits to a respective holding latch of a corresponding set of latches comprises:
applying a first latch latching clock signal to a respective Josephson junction of each first latch of a respective set of latches to transmit the qubit state information of each qubit of the plurality of qubits to a respective first latch.

24. The method of claim 23, wherein when more than one latch communicatively couples each first latch and a final latch of each set of latches, the holding latch is a latch most proximate and communicatively coupled to the final latch, and other ones of the more than one latch are one or more intermediate latches that communicatively couple each first latch to each holding latch, the method comprising alternatingly:
i) applying one or more intermediate latch latching clock signals to a respective Josephson junction of each one or more intermediate latches, and a holding latch latching clock signal to a respective Josephson junction of each holding latch of a respective set of latches, and
ii) applying one or more intermediate latch suppression clock signals to a respective Josephson junction of the one or more intermediate latches of a respective set of latches.

25. The method of claim 23, wherein the obtaining, by each shift register stage of the first set of shift register stages, qubit state information of each qubit of the first set of qubits from a respective holding latch via a respective final latch comprises:
loading the qubit state information of each qubit of the plurality of qubits held in a respective holding latch into a respective final latch of each set of latches; and,
loading the qubit state information of each qubit of the first set of qubits from a respective final latch to a respective shift register stage of the first set of shift register stages.

26. The method of claim 25, wherein:
the loading the qubit state information of each qubit of the plurality of qubits held in a respective holding latch into a respective final latch of each set of latches comprises applying a final latch latching clock signal to a respective Josephson junction of each final latch; and
the loading the qubit state information of each qubit of the first set of qubits from a respective final latch to a respective shift register stage of the first set of shift register stages comprises applying a first latching clock signal to a respective Josephson junction of each shift register stage of the first set of shift register stages.

27. The method of claim 22, wherein the obtaining, by each shift register stage of the second set of shift register stages, qubit state information of each qubit of the second set of qubits from a respective holding latch via a respective final latch comprises:
shifting the qubit state information of each qubit of the plurality of qubits from a respective holding latch to a respective final latch of each set of latches; and,
loading the qubit state information of each qubit of the second set of qubits from a respective final latch to a respective shift register stage of the second set of shift register stages.

28. The method of claim 27, wherein:
the shifting the qubit state information of each qubit of the plurality of qubits from a respective holding latch to a respective final latch of each set of latches comprises applying a final latch latching clock signal to a Josephson junction of each final latch and applying a holding latch suppression clock signal to a Josephson junction of each holding latch; and,
the loading the qubit state information of each qubit of the second set of qubits from a respective final latch to a respective shift register stage of the second set of shift register stages comprises applying a second latching clock signal to Josephson junctions of each shift register stage of the second set of shift register stages.

29. The method of claim 22, further comprising:
applying: a final latch suppression signal to a respective Josephson junction of each final latch, a first suppression clock signal to Josephson junctions of each shift register stage of the first set of shift register stages, and one of a second or third latching clock signal to propagate qubit state information from each shift register stage of the first set of shift register stages to a communicatively coupled shift register stage of a respective one of the second or third sets of shift register stages; and
applying: a final latch suppression signal to a respective Josephson junction of each final latch, a second suppression clock signal to Josephson junctions of each shift register stage of the second set of shift register stages and one of a first or a third latching clock signal to propagate qubit state information from each shift register stage of the second set of shift register stages to a communicatively coupled shift register stage of a respective one of the first or third sets of shift register stages.

30. The method of claim 22, wherein the at least one shift register comprises a plurality of shift registers that are parallel along a majority of a respective length of each shift register of the plurality of shift registers and at least two shift registers of the plurality of shift registers crosses each qubit of the first and the second sets of qubits, the propagating the qubit state information of the first set of qubits and the propagating the qubit state information of the second set of qubits comprising:
propagating qubit state information of each qubit along one of the at least two shift registers of the first plurality of shift registers that crosses said qubit, each qubit being exclusively communicatively coupled to the one of the at least two shift registers, the propagating based on first, second, and third clock signals;
shifting the qubit state information from a terminating shift register stage of the one of the at least two shift registers to a shift register stage of a respectively communicatively coupled communication shift register; and
propagating the qubit state information along the respective communication shift register to a respective readout interface based on first, second, and third communication clock signals.

31. The method of claim 30, wherein the propagating qubit state information of each qubit along one of the at least two shift registers of the plurality of shift registers that crosses said qubit comprises propagating qubit state information of all qubits coupled to a same one of the shift registers as one another along the shift register in a same direction as one another.

32. The method of claim 30, wherein the propagating qubit state information of each qubit along one of the at least two shift registers of the plurality of shift registers that crosses said qubit comprises:
propagating qubit state information of qubits on a first side of a defined shift register location along the one of the at least two shift registers in a first direction; and
propagating qubit state information of qubits on a second side of the defined shift register location along the one of the at least two shift registers in a second direction, wherein the second direction opposes the first direction.

33. The method of claim 20, wherein the at least one shift register comprises at least one shift register pair, shift registers of each shift register pair are communicatively coupled to one another via a respective interstitial bus, and, for each shift register pair, the propagating the qubit state information of the first set of qubits and the propagating the qubit state information of the second set of qubits comprises:
propagating the qubit state information along a first shift register of the shift register pair;
shifting the qubit state information from the first shift register of the shift register pair into a shift register stage of the interstitial bus;
propagating the qubit state information along a first portion of the interstitial bus;
loading the qubit state information in the interstitial bus into a shift register stage of a communication shift register;
propagating the qubit state information along the communication shift register; and
shifting the qubit state information to a readout interface.

34. The method of claim 33, further comprising:
propagating the qubit state information along a second portion of the interstitial bus;
shifting the qubit state information from the interstitial bus to a communicatively coupled shift register stage of a second shift register of the shift register pair; and
propagating the qubit state information along the second shift register of the shift register pair in a direction opposing a direction of propagation along the first shift register of the shift register pair.

35. The method of claim 33, wherein the at least one shift register comprises a first plurality of shift registers, and each pair of nearest-neighbor shift registers of the first plurality of shift registers is communicatively coupled by a respective interstitial bus, wherein the propagating the qubit state information of the first set of qubits and the propagating the qubit state information of the second set of qubits further comprises:
propagating qubit state information of qubits coupled to a first subset of shift registers of the first plurality of shift registers along a respectively coupled shift register in a first direction; and
propagating qubit state information of qubits coupled to a second subset of shift registers of the first plurality of shift registers along a respectively coupled shift register in a second direction, wherein the second direction opposes the first direction.

36. The method of claim 35, wherein the at least one shift register further comprises a second plurality of shift registers, and each pair of nearest-neighbor shift registers of the second plurality of shift registers is communicatively coupled by a respective interstitial bus, the second plurality of shift registers crossing the first plurality of shift registers at an angle, and at least one corner bus communicatively couples one shift register of the first plurality of shift registers to one shift register of the second plurality of shift registers, wherein the propagating the qubit state information of the first set of qubits and the propagating the qubit state information of the second set of qubits further comprises:
propagating qubit state information of qubits coupled to a first subset of shift registers of the second plurality of shift registers along a respectively coupled shift register in a third direction;
propagating qubit state information of qubits coupled to a second subset of shift registers of the first plurality of shift registers along a respectively coupled shift register in a fourth direction; and,
shifting the qubit state information of qubits coupled to a shift register of the first plurality of shift registers into a shift register of the second plurality of shift registers.

37. The method of claim 33, wherein the at least one shift register comprises a first plurality of shift registers, and each pair of nearest-neighbor shift registers of the first plurality of shift registers is communicatively coupled by a respective interstitial bus, wherein the plurality of qubits comprises: a first plurality of qubits including a first subset of qubits of the first and the second sets of qubits; a second plurality of qubits including a second subset of qubits of the first and the second sets of qubits; and, a third plurality of qubits including a third subset of qubits of the first and the second sets of qubits, wherein each qubit coupled to a same shift register of the first plurality of shift registers belongs to a same one of the first, the second, and the third pluralities of qubits,
wherein the obtaining, by each shift register stage of the first set of shift register stages, qubit state information of each qubit of the first set of qubits from a respective holding latch via a respective final latch comprises: obtaining qubit state information of qubits of the first set of qubits belonging to one of the first, the second, or the third pluralities of qubits; and,
wherein the obtaining, by each shift register stage of the second set of shift register stages, qubit state information of each qubit of the second set of qubits from a respective holding latch via a respective final latch comprises: obtaining qubit state information of qubits of the second set of qubits belonging to the one of the first, the second, or the third pluralities of qubits.

38. The method of claim 37, wherein:
the obtaining qubit state information of qubits of the first set of qubits belonging to one of the first, the second, or the third pluralities of qubits comprises applying a first set of latching clock signals to a subset of the first shift register stages that are correspondingly communicatively coupled to the qubits of the first set of qubits belonging to the one of the first, the second, or the third pluralities of qubits;
the obtaining qubit state information of qubits of the second set of qubits belonging to the one of the first, the second, or the third pluralities of qubits comprises applying a second set of latching clock signals to a subset of the second shift register stages that are correspondingly communicatively coupled to the qubits of the second set of qubits belonging to the one of the first, the second, or the third pluralities of qubits; and
the propagating the qubit state information of the first set of qubits and the propagating the qubit state information of the second set of qubits comprising applying suppression clock signals to at least one of shift register stages of the first and the second sets of shift register stages that are adjacent to a communication shift register and are communicatively coupled to the other ones of the first, the second, or the third pluralities of qubits, and at least one shift register stage of each interstitial bus.

39. The method of claim 37, wherein the propagating the qubit state information of the first set of qubits and the propagating the qubit state information of the second set of qubits comprises:
propagating the qubit state information of the qubits belonging to the one of the first, the second, or the third pluralities of qubits on a first side of a defined shift register location along shift registers that are communicatively coupled to the one of the first, the second, and the third pluralities of qubits in a first direction; and
propagating the qubit state information of the qubits belonging to the one of the first, the second, or the third pluralities of qubits on a second side of the defined shift register location along shift registers that are communicatively coupled to the one of the first, the second, and the third pluralities of qubits in a second direction that opposes the first direction.
